(19) United States
(12) Patent Application Publication
(10) Pub. No.: US 2025/0024687 A1
(43) Pub. Date: Jan. 16, 2025

(54) 3-DIMENSIONAL (3D) FERROELECTRIC RANDOM ACCESS MEMORY (FeRAM) AND METHOD OF MANUFACTURING THE SAME

(71) Applicant: SAMSUNG ELECTRONICS CO., LTD., SUWON-SI (KR)

(72) Inventor: Jeonil Lee, Suwon si (KR)

(21) Appl. No.: 18/422,660

(22) Filed: Jan. 25, 2024

(30) Foreign Application Priority Data
Jul. 13, 2023 (KR) 10-2023-0091351

(51) Int. Cl. H10B 53/20; H10B 53/10; H10B 53/40

(52) U.S. Cl. CPC H10B 53/20; H10B 53/10; H10B 53/40

(57) ABSTRACT

Provided are a three-dimensional (3D) ferroelectric random access memory (FeRAM) with an increased memory window per unit area and reduced process difficulty and distribution and a method of manufacturing the same. The 3D FeRAM includes a substrate, bit lines extending in a first horizontal direction spaced apart from each other in a second horizontal direction, word lines disposed over the bit line, extending in the second horizontal direction, and spaced apart from each other in the first horizontal direction, semiconductor patterns arranged at certain intervals on corresponding portions of the word lines, and ferroelectric capacitor (FeCap) structures disposed over the semiconductor patterns, wherein the FeCap structure includes a first electrode including a body portion and at least two horizontal extensions, a ferroelectric layer covering outer walls of the first electrode, and second electrodes covering the ferroelectric layer on the horizontal extensions.

### CROSS-REFERENCE TO RELATED APPLICATIONS

This application is based on and claims priority under 35 U.S.C. § 119 to Korean Patent Application No. 10-2023-0091351, filed on Jul. 13, 2023, in the Korean Intellectual Property Office, the disclosure of which is incorporated by reference herein in its entirety.

### BACKGROUND

The inventive concept relates to a semiconductor memory device, and more particularly, to a three-dimensional (3D) ferroelectric random access memory (FeRAM) and a method of manufacturing the same.

As miniaturization, multi-functionality, and high performance are expected for electronic devices, high-capacity semiconductor memory devices are sought, and an increasing degree of integration is called for to provide high-capacity semiconductor memory devices. Because the degree of integration of conventional two-dimensional (2D) semiconductor memory devices is mainly determined by the area occupied by a unit memory cell, the degree of integration of 2D semiconductor memory devices is increasing but is still limited. Therefore, a three-dimensional (3D) semiconductor memory device with increased memory capacity achieved by stacking a plurality of memory cells in a vertical direction on a substrate has been proposed.

### SUMMARY

The inventive concept provides a three-dimensional (3D) ferroelectric random access memory (FeRAM) with an increased memory window per unit area, and reduced process difficulty and distribution, and a method of manufacturing the same.

According to an aspect of the inventive concept, there is provided a three-dimensional (3D) ferroelectric random access memory (FeRAM) including bit lines extending in a first horizontal direction on a substrate and spaced apart from each other in a second horizontal direction perpendicular to the first horizontal direction, word lines disposed over the bit line, extending in the second horizontal direction, and spaced apart from each other in the first horizontal direction, semiconductor patterns arranged at certain intervals on corresponding portions of the word lines with a gate dielectric layer therebetween, and ferroelectric capacitor (FeCap) structures over the semiconductor patterns in the vertical direction, wherein the FeCap structure includes a first electrode including a body portion extending in the vertical direction from a semiconductor pattern and at least two horizontal extensions extending from side surfaces of the body portion in the first horizontal direction and located at different levels, a ferroelectric layer covering outer walls of the body portion and the horizontal extensions, and second electrodes covering the ferroelectric layer on the horizontal extensions.

According to another aspect of the inventive concept, there is provided a three-dimensional (3D) ferroelectric random access memory (FeRAM) including a substrate, bit lines extending in a first horizontal direction on the substrate and spaced apart from each other in a second horizontal direction perpendicular to the first horizontal direction, a selection transistor (Tr) including word lines arranged over the bit lines in a vertical direction, extending in the second horizontal direction, and spaced apart from each other in the first horizontal direction, and semiconductor patterns arranged at intervals on corresponding portions of the word lines with a gate dielectric layer therebetween in the second horizontal direction, and a FeCap structure having a plurality of capacitors on the selection Tr, wherein the FeCap structure includes a first electrode including a body portion extending in the vertical direction from a semiconductor pattern and a plurality of horizontal extensions extending from a side surface of the body portion in the first horizontal direction, a ferroelectric layer covering outer walls of the body portion and the horizontal extensions, a plurality of second electrodes covering the ferroelectric layer of the horizontal extensions, where the 3D FeRAM has a structure in which the plurality of FeCaps are electrically connected to one selection Tr.

According to another aspect of the inventive concept, there is provided a three-dimensional (3D) ferroelectric random access memory (FeRAM) including a substrate, bit lines extending in a first horizontal direction on the substrate and spaced apart from each other in a second horizontal direction perpendicular to the first horizontal direction, at least one transistor (TR) on the bit line; and a FeCap structure on the at least one TR, wherein the FeCap structure includes a first electrode comprising a body portion extending in a vertical direction from the at least one Tr and a plurality of horizontal extensions extending in the first horizontal direction from a side surface of the body portion and located at different levels, a ferroelectric layer covering outer walls of the body portion and the horizontal extensions, and a plurality of second electrodes covering the ferroelectric layer on the horizontal extensions.

### BRIEF DESCRIPTION OF THE DRAWINGS

Embodiments of the inventive concept will be more clearly understood from the following detailed description taken in conjunction with the accompanying drawings in which:

FIG. 1 is an equivalent circuit diagram for a three-dimensional (3D) ferroelectric random access memory (FeRAM) according to an embodiment;

FIGS. 2A and 2B are a perspective view and a top view, respectively, of a 3D FeRAM according to an embodiment;

FIGS. 3A to 3C are an enlarged plan view and cross-sectional views of a portion A of the 3D FeRAM of FIG. 2B;

FIGS. 4A and 4B are an equivalent circuit diagram and a cross-sectional view, respectively, of a 3D FeRAM according to an embodiment; and

FIGS. 5A to 15C are a plan view and cross-sectional views schematically showing a process of manufacturing the 3D FeRAM of FIG. 2B.

### DETAILED DESCRIPTION OF THE EMBODIMENTS

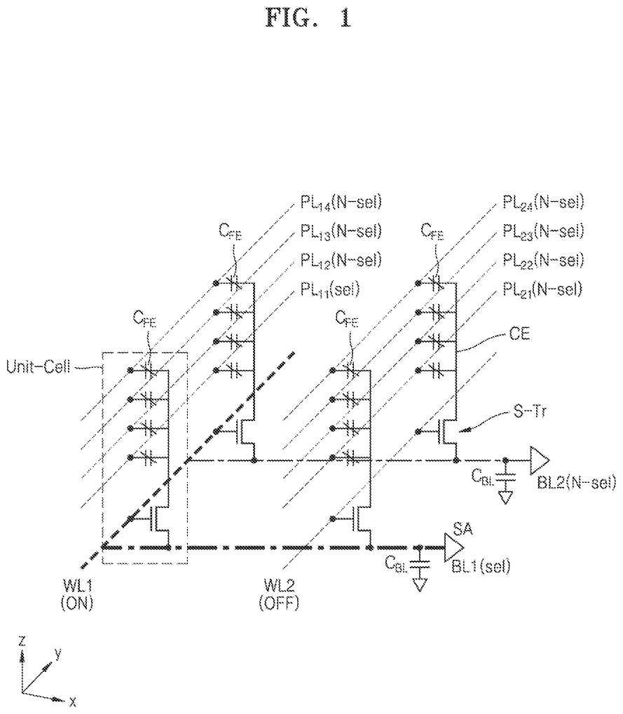

FIG. 1 is an equivalent circuit diagram for a three-dimensional (3D) ferroelectric random access memory (FeRAM) according to an embodiment.

Referring to FIG. 1, a 3D FeRAM 100 according to the present embodiment may include bit lines BL1 and BL2, a selection transistor S-Tr, and a ferroelectric capacitor (FeCap) C_{FE}. The bit lines BL1 and BL2 and word lines WL1 and WL2 connected to a gate of the selection transistor S-Tr may each be arranged 2-dimensionally. For example, the bit lines BL1 and BL2 may each extend in the x direction and be spaced apart from each other in the y direction. Additionally, the word lines WL1 and WL2 may each extend in the y direction and be spaced apart from each other along the x direction.

In various embodiments, a plurality of selection transistors S-Tr may be connected in parallel to each of the bit lines BL1 and BL2. For example, a first bit line BL1 may be commonly connected to first ends of source/drains of the selection transistors S-Tr arranged in the x direction in a first row, and a second bit line BL2 may be commonly connected to first ends of source/drains of the selection transistors S-Tr arranged in the x direction in a second row. Also, gates of the selection transistors S-Tr arranged in the y direction in the first column may be commonly connected to a first word line WL1, and the gates of the selection transistors S-Tr arranged in the y direction in the second column may be commonly connected to a second word line WL2.

In various embodiments, the FeCap C_{FE} may be connected to second ends of the source/drains of the selection transistors S-Tr. As shown in the circuit diagram of FIG. 1, a plurality of FeCaps C_{FE} may be connected to a source/drain of one selection transistor S-Tr in a vertical direction, that is, the z direction, where the plurality of FeCaps C_{FE} connected to the same source/drain may be connected in parallel to each other. For example, a plurality of FeCaps C_{FE} arranged in the z direction may be connected together to a common electrode CE and may each be connected to a corresponding plate line electrode PL, where the common electrode CE is connected to the same source/drain of the selection transistor S-Tr. Furthermore, the FeCaps C_{FE} at the same level in the z direction may be connected to the plate line electrode PL in the y direction.

In various embodiments, four FeCaps C_{FE} spaced apart from one another in the z direction may be considered as one set of independent capacitors (Caps), where set Caps may be arranged at the locations of the selection transistors S-Tr on the x-y plane. In addition, set plate line electrodes PL₁ and PL₂ connected to a set Cap may extend in the y direction and be spaced apart from each other in the x direction. Because the set Cap includes four FeCaps C_{FE} spaced apart from one another in the z direction, first set plate line electrodes PL₁ in a first column may include first to fourth plate line electrodes PL₁₁ to PL₁₄ spaced apart from one another in the z direction, and second set plate line electrodes PL₂ in a second column may include first to fourth plate line electrodes PL₂₁ to PL₂₄ spaced apart from one another in the z direction. While an embodiment of the FeRAM is described as having four FeCaps, this is for illustrative purposes only, and other quantities of FeCaps may be employed in a device without departing from the scope of the disclosure and claims.

In various embodiments, the 3D FeRAM 100 may have the above-stated connection relationship and may have a structure in which a plurality of FeCaps C_{FE}, e.g., four FeCaps C_{FE}, are connected to one selection transistor S-Tr. Therefore, the 3D FeRAM 100 can be described as a 1TnC structure, indicating that n (n is an integer greater than or equal to 2) capacitors (Caps) are connected to single, common transistor (Tr). For reference, in the circuit diagram of FIG. 1, as indicated by a thick dotted line and a thick double-dashed line, the selection transistors S-Tr on the left side in the x direction may be turned on, as the first bit line BL1 and the first word line WL1 are selected, and, as the first bit line BL1 and a first plate line electrode PL₁₁ of the first set plate line electrodes PL₁ are selected, information may be stored in or read from a corresponding FeCap C_{FE}. In the case of reading, a sense amplifier (SA) connected to the first bit line BL1 may be used. In the circuit diagram of FIG. 1, (sel) may denote a selected line and (N-sel) may denote unselected lines.

In various embodiments of the 3D FeRAM 100, a plurality of FeCaps C_{FE} connected to the source/drain of the selection transistor S-Tr are spaced apart in the z direction and may form a quadrangular pillar-like shape lying in one direction, e.g., the x direction. Therefore, as the FeCaps C_{FE} are formed on five surfaces including four side surfaces and the bottom surface of a quadrangular pillar, the capacitance per unit area may be significantly increased, where the capacitance may be increased in proportion to the number of capacitors (e.g., each FeCaps C_{FE} connected to the source/drain has essentially the same capacitance). Also, as compared to the typical Vertical Stack (VS)-DRAM structure, because a cell transistor may not be utilized, process difficulty/distribution may be significantly reduced.

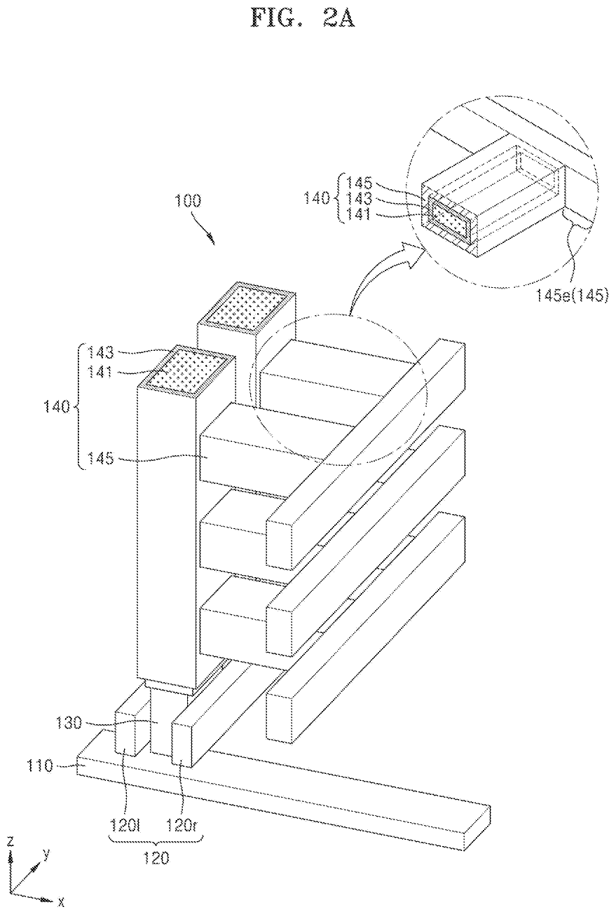

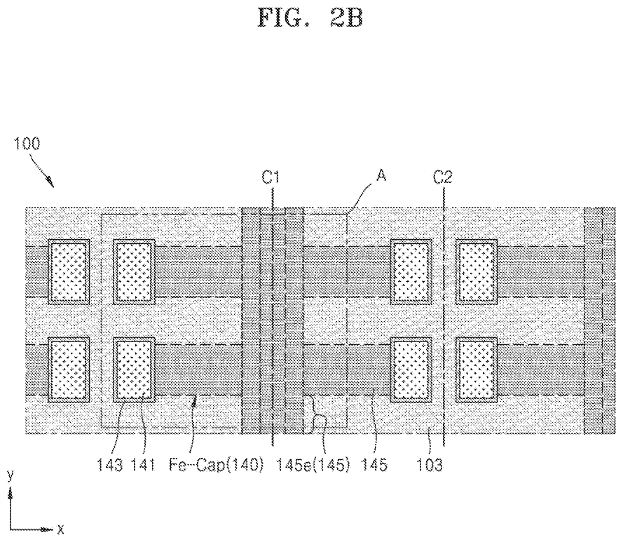

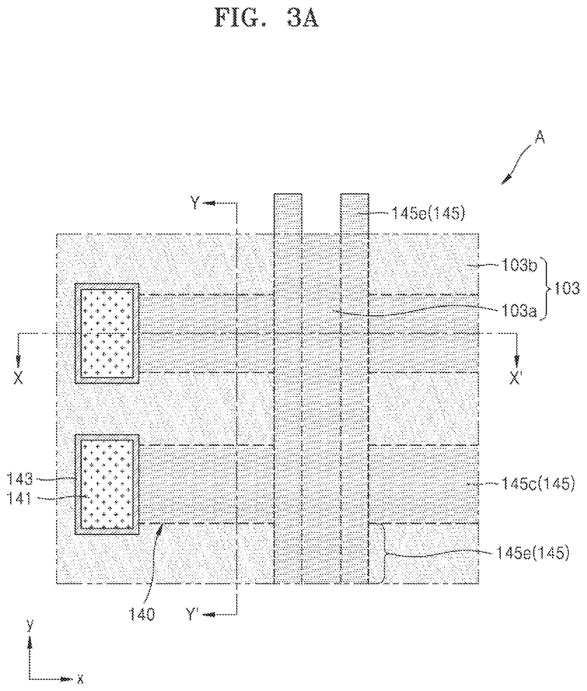

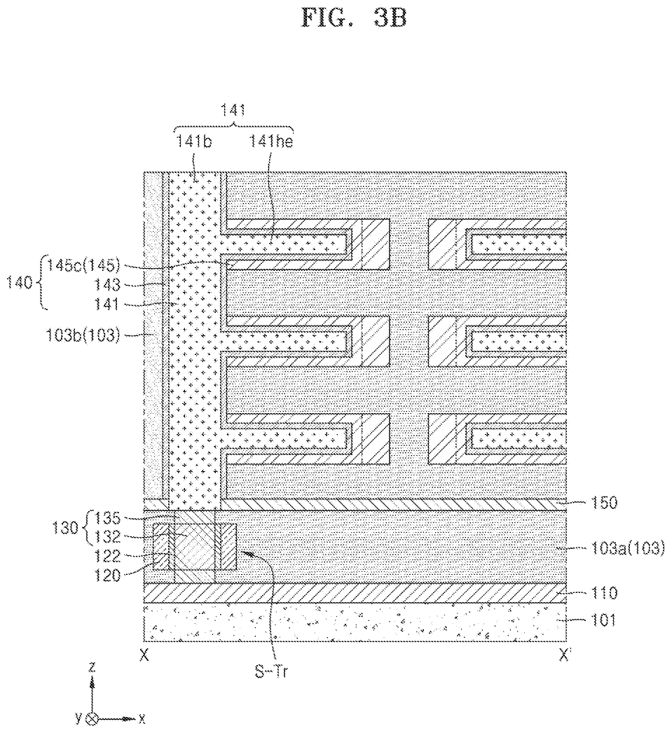

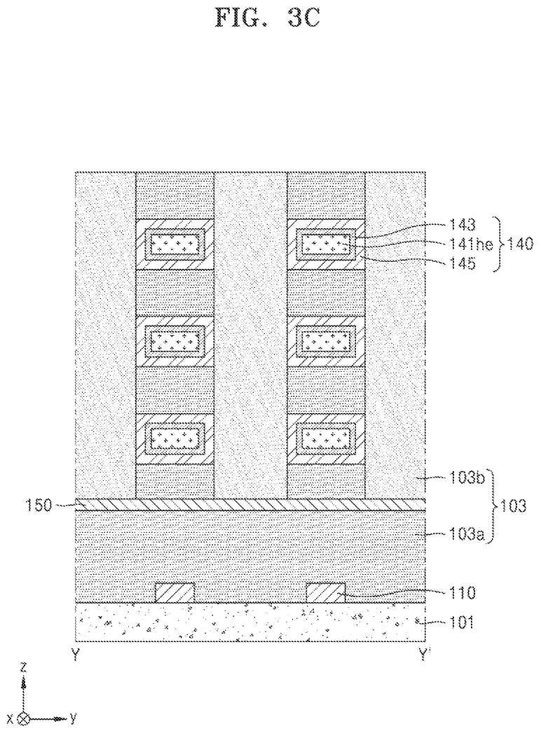

FIGS. 2A and 2B are a perspective view and a top view, respectively, of a 3D FeRAM according to an embodiment, and FIG. 2A is a perspective view of a portion corresponding to one word line in the 3D FeRAM of FIG. 2B. FIGS. 3A to 3C are an enlarged plan view and cross-sectional views of a portion A of the 3D FeRAM of FIG. 2B, wherein FIG. 3B is a cross-sectional view taken along a line X-X′ of FIG. 3A, and FIG. 3C is a cross-sectional view taken along a line Y-Y′ of FIG. 3A. Descriptions of FIGS. 2A and 2B are given below with reference to FIG. 1, and descriptions already given above with reference to FIG. 1 may be briefly given or omitted.

Referring to FIGS. 2A to 3C, the 3D FeRAM 100 according to the present embodiment includes a substrate 101, a bit line 110, a word line 120, a semiconductor pattern 130, and a FeCap 140, as shown for example in FIG. 3B. The 3D FeRAM 100 according to the present embodiment may have a horizontally symmetrical structure around a first center line C1 disposed between second electrodes 145 of two FeCaps 140 adjacent to each other in the x direction, or a second center line C2 disposed between first electrodes 141 of two FeCaps 140 adjacent to each other in the x direction, as shown for example in FIG. 2B.

In various embodiments, the substrate 101 may include silicon (Si), e.g., monocrystalline Si, polycrystalline Si (poly Si), or amorphous Si. However, the material of the substrate 101 is not limited to Si, where for example, according to some embodiments, the substrate 101 may include a group IV semiconductor, including, but not limited to, germanium (Ge), a group IV-IV compound semiconductor like silicon germanium (SiGe) or silicon carbide (SiC), or a group III-V compound semiconductor like gallium arsenide (GaAs), indium arsenide (InAs), and indium phosphide (InP).

In various embodiments, the substrate 101 may be a Si bulk substrate, a silicon-on-insulator (SOI) substrate, or a germanium-on-insulator (GeOI) substrate. The substrate 101 is not limited to a bulk substrate, a SOI substrate, or a GeOI substrate, and may also be a substrate based on an epitaxial wafer, a polished wafer, or an annealed wafer. The substrate 101 may include a conductive region, for example, a well doped with impurities or a various structure doped with impurities. Also, the substrate 101 may be configured as a P-type substrate or an N-type substrate depending on the type of impurity ions doped thereto. A peripheral circuit and a wiring layer connected to the peripheral circuit may be arranged on a portion of the substrate 101.

In various embodiments, bit lines 110 extend in the x direction on the substrate 101 and may be arranged to be spaced apart from each other in the y direction. The bit lines 110 may be arranged to be connected to a selection transistor S-Tr, and more particularly, an impurity region 135 of the selection transistor S-Tr. The impurity region 135 may correspond to the source/drain region of the selection transistor S-Tr. The bit line 110 may include a conductive material, where the bit line 110 may include, for example, a doped semiconductor material, a metal, a conductive metal nitride, a metal-semiconductor compound, or combination thereof.

In various embodiments, the word line 120 may be disposed above and spaced apart from the bit line 110 in the vertical direction, e.g., the z direction, over the substrate 101. Word lines 120 may extend in the y direction on the bit line 110 and may be arranged to be spaced apart from each other in the x direction. As shown in FIG. 3B, the word lines 120 may be arranged on both sides of the semiconductor pattern 130 in the x direction, where the semiconductor pattern 130 is between the word lines 120. For example, the word lines 120 may include a left word line 1201 and a right word line 120r with the semiconductor pattern 130 therebetween, as shown, for example, in FIG. 2A. A gate dielectric layer 122 may be provided between the semiconductor pattern 130 and the word lines 120, as shown, for example, in FIG. 3B. According to various embodiments, a word line 120 may be located on only one side of the semiconductor pattern 130 in the x direction. The word line 120 may include a conductive material, where the word line 120 may include, for example, a doped semiconductor material, a metal, a conductive metal nitride, a metal-semiconductor compound, or a combination thereof.

In various embodiments, semiconductor patterns 130 may be arranged at certain predefined intervals in the x direction and y direction. For example, the semiconductor patterns 130 may be arranged at locations where the bit lines 110 are positioned in the x direction. Also, the semiconductor patterns 130 may be arranged to be spaced apart from each other in the y direction on corresponding word lines 120 with the gate dielectric layer 122 therebetween. In other words, the semiconductor pattern 130 may be disposed at a cross-point location, where the word line 120 crosses over the bit line 110.

In various embodiments, the semiconductor pattern 130 may include a channel region 132 at the center portion thereof in the z direction and impurity regions 135 corresponding to source/drain on both sides of the channel region 132 in the z direction. The word line 120 may be located on the channel region 132 with the gate dielectric layer 122 therebetween. The semiconductor pattern 130 and a word line 120 may constitute a selection transistor S-Tr, and the bit line 110 may be electrically connected to a first impurity region 135 on one side of the semiconductor pattern 130, and the FeCap 140 may be connected to a second impurity region 135 on the side of the semiconductor pattern 130 opposite the first impurity region 135.

In various embodiments, the semiconductor pattern 130 may include an undoped semiconductor material or a doped semiconductor material. According to various embodiments, the semiconductor pattern 130 may include a semiconductor material, such as monocrystalline Si, polycrystalline Si, SiGe, or SiC. According to various embodiments, the semiconductor pattern 130 may include a 2D semiconductor material including transition metal dichalcogenides (TMD), including, but not limited to, CuS₂, CuSe₂, WSe₂, MoS₂, MoSe₂, and WS₂, hexagonal boron nitride (h-BN), graphene, carbon nano-tubes (CNT), and combinations thereof. According to various embodiments, the semiconductor pattern 130 may include an amorphous metal oxide semiconductor material, a polycrystalline metal oxide semiconductor material, or a combination thereof. For example, metal oxide semiconductor materials may include, but not be limited to In—Zn-based oxide (IZO), Zn—Sn-based oxide (ZTO), In—Ga-based oxide (IGO), Y—Zn-based oxide (YZO), and In—Ga—Zn-based oxide (IGZO). However, the material constituting the semiconductor pattern 130 is not limited to the above-stated materials.

In various embodiments, the semiconductor pattern 130 may have a quadrangular pillar-like structure corresponding to the quadrangular pillar-like structure of a body portion 141b of a first electrode 141 of the FeCap 140. For example, the semiconductor pattern 130 may have a quadrangular pillar-like shape extending in the z direction, as shown for example, in FIG. 2A. The semiconductor pattern 130 may include the channel region 132 at the center portion thereof in the z direction and the impurity regions 135 on both sides of the channel region 132 in the z direction, as shown for example in FIG. 3B. A lower impurity region 135 may be connected to the bit line 110, and an upper impurity region 135 may be connected to the first electrode 141 of the FeCap 140, where the upper and lower impurity regions 135 are on opposite sides of the channel region 132.

The impurity regions 135 may be formed by implanting dopant ions into both sides of the semiconductor pattern 130 in the z direction, where the implanted dopants can be n-type or p-type dopants. The impurity regions 135 may form a source junction and a drain junction of the selection transistor S-Tr. As described above, the semiconductor pattern 130 and a portion of the word line 120 corresponding thereto may constitute the selection transistor S-Tr. Also, the semiconductor pattern 130 may include the channel region 132 disposed adjacent to the word line 120 through the gate dielectric layer 122, therebetween and may include the impurity regions 135 corresponding to a source/drain on both sides of the channel region 132 in the z direction. A silicide layer may be formed between the impurity region 135 and the bit line 110 and between the impurity region 135 and the first electrode 141, as an ohmic contact with a metal. The silicide film may include, for example, at least one of titanium (Ti) silicide, tungsten (W) silicide, cobalt (Co) silicide, or nickel (Ni) silicide.

In various embodiments, the FeCap 140 may include the first electrode 141, a ferroelectric layer 143, and a second electrode 145. The FeCap 140 may each be disposed on the semiconductor pattern 130 or the selection transistor S-Tr and electrically connected to the semiconductor pattern 130 or the selection transistor S-Tr, where the FeCap 140 may be disposed at a cross-point location where the word line 120 crosses over the bit line 110, and are proximal to each other in relation to the x-y plane.

In various embodiments, the first electrode 141 may include a body portion 141b extending in the vertical direction, for example the z direction, on the substrate 101, and a plurality of horizontal extensions 141he extending in the x direction from side surfaces of the body portion 141b. The plurality of horizontal extensions 141he may be located at different levels in the z direction (e.g., different vertical distances from the substrate 101). As shown in FIG. 3B, the first electrode 141 is commonly connected to the FeCaps C_{FE} formed by the horizontal extensions 141he, and thus the first electrode 141 may be referred to as a common electrode. Also, the first electrode 141 connected to one semiconductor pattern 130 may have a structure in which the entire first electrode 141 is integrally connected to the semiconductor pattern 130.

In various embodiments, the body portion 141b may have a quadrangular pillar-like shape. Therefore, as shown in FIG. 3B, the horizontal cross-section of the body portion 141b may have a quadrangular shape. The body portion 141b may extend through an etch stop layer 150 and be electrically connected to the semiconductor pattern 130 at the bottom surface of the body portion 141b. The etch stop layer 150 may be disposed on a first insulation layer 103a, the surface of the substrate 101, over the bit line 110, the word line 120, and the semiconductor pattern 130.

In various embodiments, a horizontal extension 141he may extend from a side surface of the body portion 141b in the x direction, where the horizontal extension 141he may have a quadrangular pillar-like shape (e.g., a bar shape) extending in the x direction. In other words, the horizontal extension 141he may have the shape of a quadrangular pillar lying down (i.e., oriented) in the x direction. Therefore, as shown in FIG. 3C, the vertical cross-section of the horizontal extension 141he perpendicular to the x direction may have a quadrangular shape. Also, the vertical cross-section of the horizontal extension 141he perpendicular to the y direction may have a quadrangular shape elongated in the x direction.

In FIG. 3B, three horizontal extensions 141he are shown arranged on a body portion 141b, where the three horizontal extensions 141he and the body portion 141b are connected to form an “E” shape. However, the number of horizontal extensions 141he arranged along one body portion 141b is not limited to three. For example, in the 3D FeRAM 100 according to the present embodiment, one, two, four, or more horizontal extensions 141he may be arranged along a body portion 141b.

In various embodiments, as shown in FIG. 3B, the horizontal extensions 141he of two body portions 141b adjacent to each other in the x direction may extend in opposite directions to each other in the x direction. For example, in the x direction, the body portion 141b and the horizontal extension 141he of a first first electrode 141, the horizontal extension 141he and the body portion 141b of a second first electrode 141, the body portion 141b and the horizontal extension 141he of a third first electrode 141 may be arranged in the order stated. Therefore, the horizontal extension 141he of the first first electrode 141 and the horizontal extension 141he of the second first electrode 141 are adjacent to each other, and the body portion 141b of the second first electrode 141 and the body portion 141b of the third first electrode 141 may be adjacent to each other.

In various embodiments, the first electrode 141 may be a conductive material, including, but not limited to, a doped semiconductor material, a metal, a conductive metal nitride, and a conductive metal oxide. The metal may include, for example, ruthenium, iridium, titanium, tantalum, etc. The conductive metal nitride may include, for example, titanium nitride, tantalum nitride, niobium nitride, tungsten nitride, etc. The conductive metal oxides may include, for example, iridium oxide, niobium oxide, etc. However, the material constituting the first electrode 141 is not limited to the above-stated materials.

In various embodiments, the ferroelectric layer 143 may have a structure that covers the outer side surfaces of the first electrode 141, where the ferroelectric layer 143 may surround at least a portion of the body portion 141b. The ferroelectric layer 143 may cover four side surfaces of the body portion 141b of the first electrode 141, where the ferroelectric layer 143 is between the horizontal extension 141he. For example, a portion of the ferroelectric layer 143 covering the body portion 141b may have the annular shape of a quadrangular tube extending in the z direction. Therefore, as shown, for example, in FIG. 3A, at a level without the horizontal extension 141he, the horizontal cross-section of a portion of the ferroelectric layer 143 of the body portion 141b perpendicular to the z direction may have a quadrangular ring-like shape.

In various embodiments, the ferroelectric layer 143 may cover the outer side, top, bottom, and end surfaces of the horizontal extension 141he of the first electrode 141, as shown, for example, in FIG. 3B. The ferroelectric layer 143 may cover the four side surfaces and the bottom surface of the horizontal extension 141he. For example, a portion of the ferroelectric layer 143 covering the horizontal extension 141he may have the annular shape of a quadrangular tube extending in the x direction with a distal end closed and the proximal end connected to the body portion 141b. Therefore, as shown in FIG. 3C, the vertical cross-section of the ferroelectric layer 143 of the horizontal extension 141he perpendicular to the x direction may have a quadrangular ring-like shape. Also, as shown in FIG. 3B, the vertical cross-section of a portion of the ferroelectric layer 143 of the horizontal extension 141he perpendicular to the y direction may have a ‘⊏’ shape (e.g., a squared-off “C” shape).

In terms of the overall structure of the ferroelectric layer 143, the ferroelectric layer 143 has a vertical quadrangular tube-like portion extending in the z direction in correspondence to the body portion 141b, and a horizontal quadrangular tube-like portion extending in the x direction in correspondence to the horizontal extension 141he. The vertical quadrangular tube-like portion may have both ends (e.g., top and bottom) open in the z direction, and the horizontal quadrangular tube-like portion may have one end closed in the x direction. Also, on one side of the vertical quadrangular tube-like portion, portions corresponding to the horizontal extensions 141he may be opened, and the horizontal quadrangular tube-like portions may be connected thereto. Meanwhile, in correspondence to the first electrode 141, the ferroelectric layer 143 may also have a structure in which the entire ferroelectric layer 143 is integrally connected forming a continuous layer on the body portion 141b and horizontal extension 141he.

In various embodiments, the ferroelectric layer 143 may include a ferroelectric material, where for example, the ferroelectric layer 143 may include a hafnium (Hf)-based oxide. The Hf-based oxides may include hafnium oxide (HfO), hafnium silicate (HfSiO), hafnium oxynitride (HfON), and hafnium silicon oxynitride (HfSiON). When the ferroelectric layer 143 includes an Hf-based oxide, the ferroelectric layer 143 may include at least one dopant from among Zr, Si, Al, Y, Gd, La, Sc, and Sr. However, the materials constituting the ferroelectric layer 143 are not limited to the above-stated materials.

In various embodiments, the ferroelectric layer 143 may include a single film or a multi-layer. When the ferroelectric layer 143 includes a multi-layer, the outermost layers on both sides may include ferroelectric thin-films, where for example, the ferroelectric layer 143 may have a triple-layer structure including a first ferroelectric thin-film, an AlO thin-film, and a second ferroelectric thin-film. In various embodiments, the ferroelectric layer 143 may have a quintuple-layer structure including a first ferroelectric thin-film, a first AlO thin-film, a second ferroelectric thin-film, a second AlO thin-film, and a third ferroelectric thin-film. However, the multi-layer structure of the ferroelectric layer 143 is not limited to a triple-layer or quintuple-layer structure.

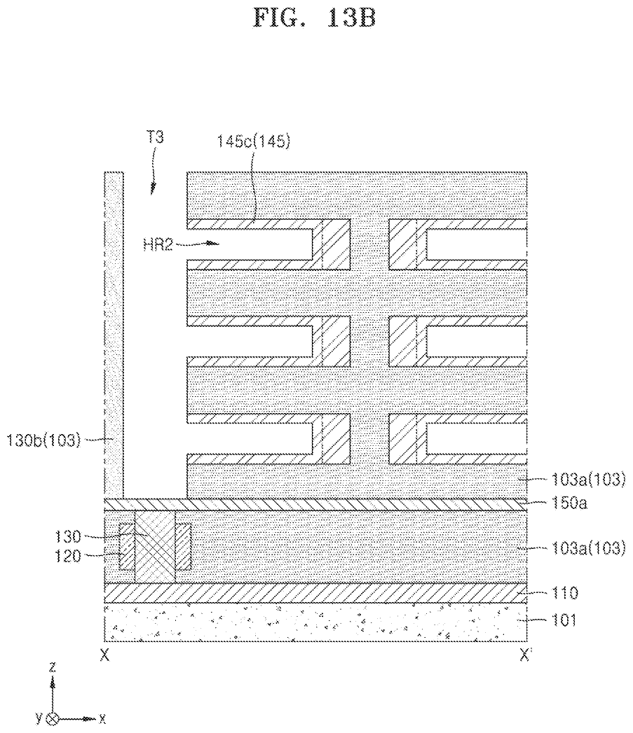

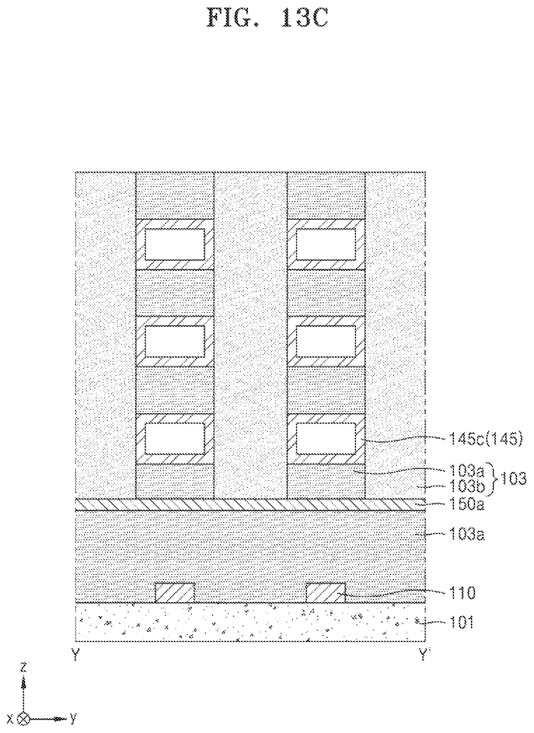

In various embodiments, the second electrode 145 may include a cover portion 145c, as shown, for example, in FIG. 13B, that covers the outer side surfaces of the ferroelectric layer 143 of the horizontal extension 141he of the first electrode 141 and an extension 145e, as shown in FIG. 2A, extending in the y direction. The cover portion 145c of the second electrode 145 may cover the horizontal quadrangular tube-like portion of the ferroelectric layer 143, where the cover portion 145c can surround the ferroelectric layer 143 on the horizontal extension 141he. For example, the cover portion 145c may have the shape of a quadrangular tube extending in the x direction with one end closed. Therefore, as shown in FIG. 13C, the vertical cross-section of the cover portion 145c perpendicular to the x direction may have a quadrangular ring-like shape. Also, as shown in FIG. 13B, the vertical cross-section of the cover portion 145c perpendicular to the y direction may have a ‘⊏’ shape (e.g., a squared-off “C” shape).

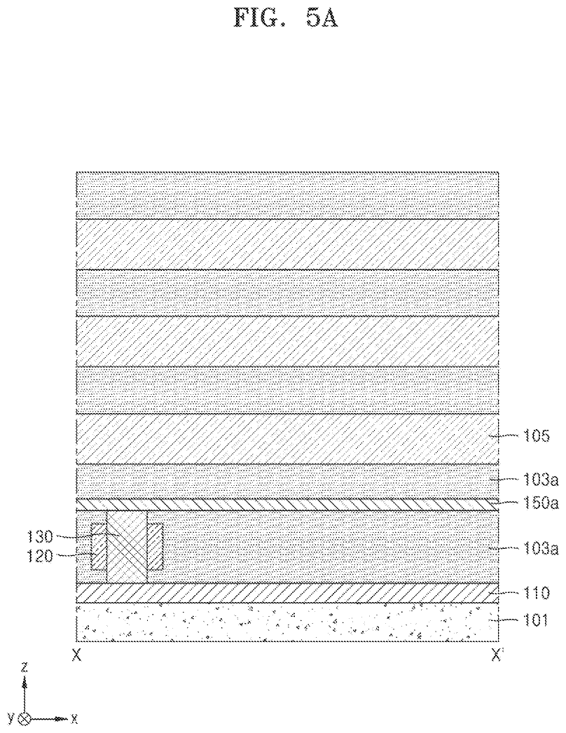

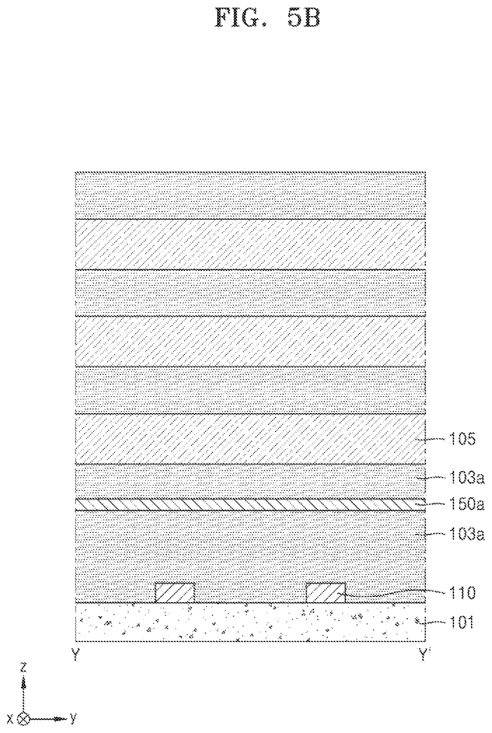

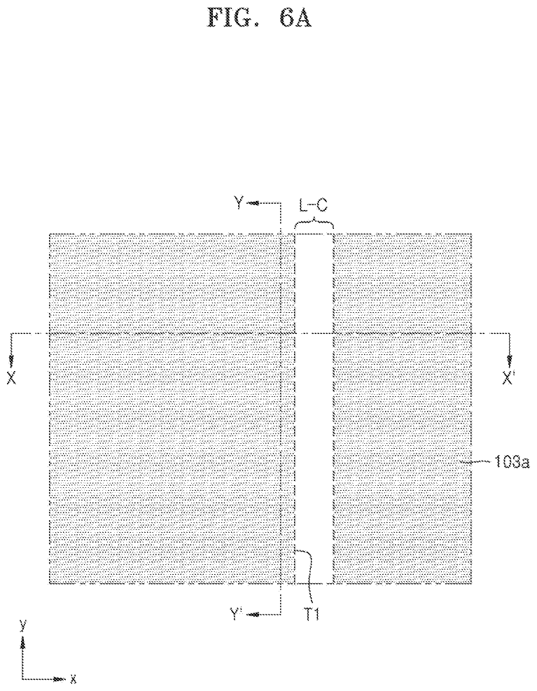

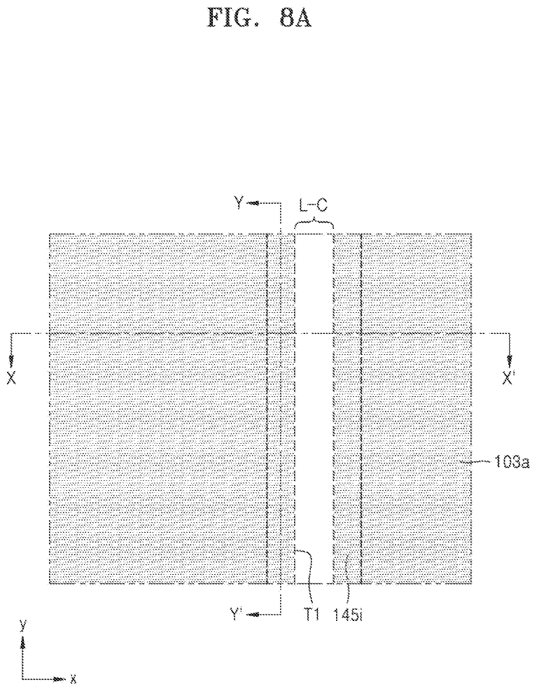

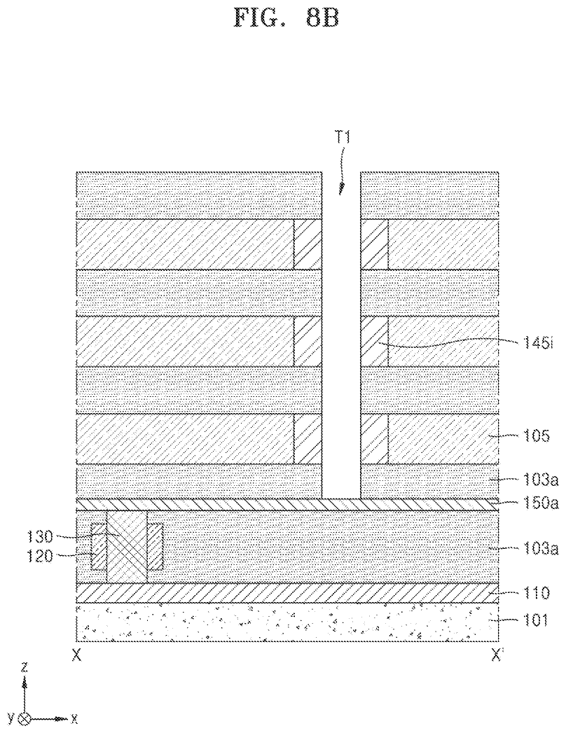

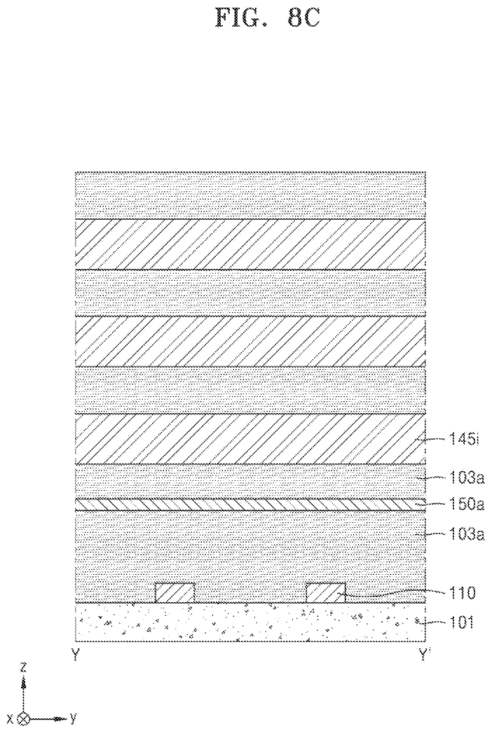

In various embodiments, in the closed quadrangular tube-like shape of the cover portion 145c, the closed end may be thicker than the other four side portions, as shown, for example, in FIG. 13B. For example, in the ‘E’ shape, the vertical portion may be thicker than upper and lower horizontal portions. This is because, as indicated by the dotted lines, in the process of forming the second electrode 145, a portion of an initial second electrode (referred to as 145i in FIG. 8B) is merged with the closed distal end of the cover portion 145c. The thickness of the closed end of the cover portion 145c will be described in more detail with reference to FIGS. 5A to 15C.

In various embodiments, as shown, for example, in FIGS. 3A and 3B, the extension 145e may extend in the y direction from the closed side of the cover portion 145c. For example, the extension 145e may correspond to a portion of the initial second electrode 145i excluding a portion of the initial second electrode 145i that meets the closed side of the cover portion 145c. The extension 145e may connect the second electrodes 145 located at the same level in the z direction to each other in the y direction. Therefore, the closed end of the cover portion 145c of the second electrode 145 and the extension 145e may form a plate line shape extending in the y direction at the same level in the z direction. Therefore, the second electrode 145 may be referred to as a plate line electrode. The second electrode 145 may include substantially the same conductive material as the first electrode 141. However, according to various embodiments, the second electrode 145 may include a conductive material different from that of the first electrode 141.

Furthermore, portions of the substrate 101 other than portions of the substrate 101 corresponding to the bit line 110, the word line 120, the semiconductor pattern 130, the FeCap 140, and the etch stop layer 150 may be covered by an insulation layer 103, as shown, for example, in FIG. 3B. The insulation layer 103 may include, for example, an oxide layer, such as a silicon oxide layer (SiO₂). However, the material constituting the insulation layer 103 is not limited to an oxide layer. FIGS. 3A to 3C show that the insulation layer 103 is divided into a first insulation layer 103a and a second insulation layer 103b. However, the difference between the first insulation layer 103a and the second insulation layer 103b is the time of formation, where the first insulation layer 103a is formed prior to the second insulation layer 103b, and both the first insulation layer 103a and the second insulation layer 103b may include the same material, e.g., an oxide layer.

As described above, the first electrode 141, the ferroelectric layer 143, and the second electrode 145 may constitute the FeCap 140. This FeCap 140 may store information values, for example, of [0] or [1] due to the hysteresis characteristic of the ferroelectric layer 143 with respect to the dielectric polarization. One capacitor may be configured per one second electrode 145. In other words, in the FcCap 140, the horizontal extension 141he of the first electrode 141, the horizontal quadrangular tube-like portion of the ferroelectric layer 143, and the cover portion 145c of the second electrode 145 may constitute a capacitor. As a result, as shown in FIG. 3B, one first electrode 141 and one ferroelectric layer 143 may meet three separate second electrodes 145, thereby forming three FeCaps 140, where the three FeCaps 140 may be connected to one semiconductor pattern 130 or one selection transistor S-Tr.

For reference, FeRAM may be distinguished into a 1Tr1Cap (i.e., 1T1C) type device in which one FeCap is disposed in one transistor Tr, and a 1Tr type device in which the gate dielectric layer of a field effect transistor (FET) is replaced with a ferroelectric layer, similar to a FET. The 3D FeRAM 100, according to the present embodiment may belong to the 1Tr1Cap type, for example. The 3D FeRAM 100 according to the present embodiment, may have n FeCaps arranged at one selection transistor S-Tr. Therefore, the 3D FeRAM 100 may have a 1TrnCap structure, that is, a 1TnC structure with a plurality of separate capacitors, FeCaps.

In various embodiments, the 3D FeRAM 100 has a 1TnC structure, and may also have a pillar-like structure in which the FeCap 140 is oriented in a sideways direction, e.g., the x direction, where the pillar-like structure is essentially parallel with the plane of the substrate 101. The lying pillar-like shaped portion of the FeCap 140 is a portion constituting a capacitor, and the lying pillar-like portion may have, for example, a quadrangular pillar-like shape. Therefore, the memory window (MW) per unit area of the 3D FeRAM 100 may be significantly increased. Also, as compared to the VS-DRAM structure, in the 3D FeRAM 100, the selection transistor S-Tr is disposed and there is no cell transistor for each layer, and thus it may be greatly advantageous in terms of process difficulty/distribution.

Also, the 1T1C structure and the 1TnC structure may resolve the endurance problem of an FcRAM (e.g., FcFET) having the 1Tr structure and may also resolve the problem of the VS-DRAM that monocrystalline Si channels need to be stacked due to the leakage issue. Therefore, due to the 1TnC structure of the 3D FeRAM 100, leakage problems may not occur even when poly-Si is used in the semiconductor pattern 130 constituting a channel. Also, in the 3D FeRAM 100, the second electrodes 145 may be separated from each other in the z direction. In this regard, as the second electrode 145 are separated from each other in the z direction, the read disturbance problem due to the structure in which all of the second electrodes 145 are combined with one another may be resolved, and thus the reliability of an FeRAM may be significantly improved.

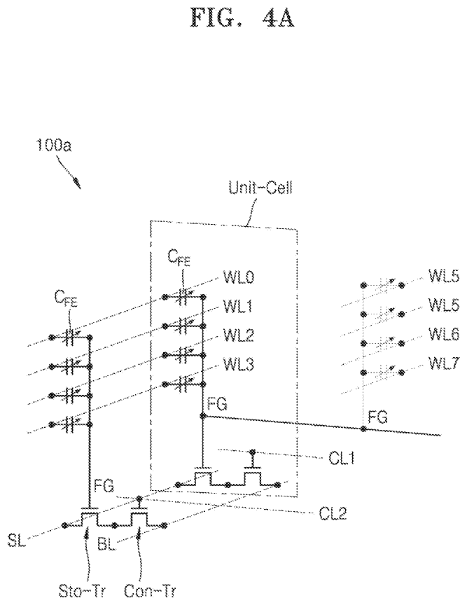

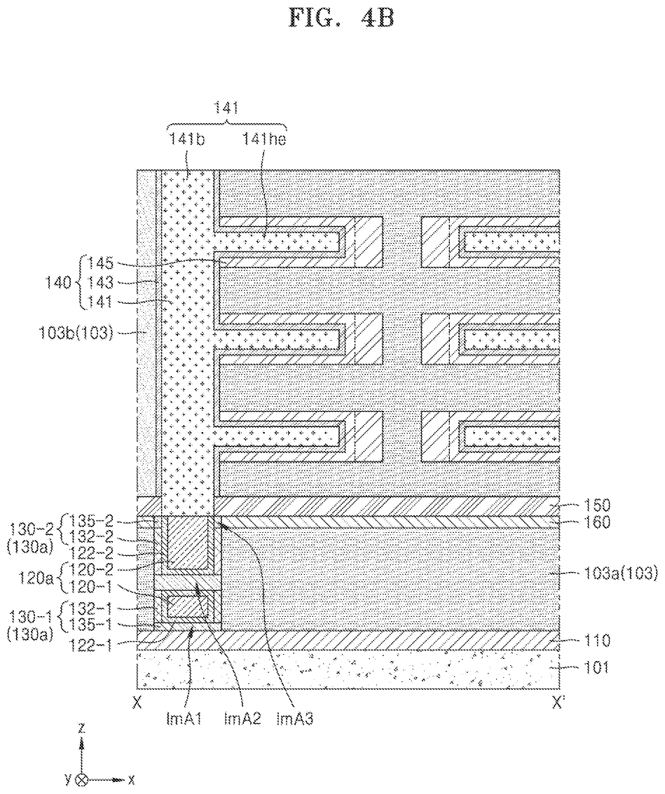

FIGS. 4A and 4B are an equivalent circuit diagram and a cross-sectional view of a 3D FeRAM, according to an embodiment, where the cross-sectional view of FIG. 4B corresponds to the cross-sectional view of FIG. 3B. Descriptions already given above with reference to FIGS. 1 to 3C will be briefly given or omitted.

Referring to FIGS. 4A and 4B, a 3D FeRAM 100a may be different from the 3D FeRAM 100 of FIG. 3B in terms of the gate line 120a, the structure of a semiconductor pattern 130a corresponding thereto, and an additionally disposed source line 160. In the 3D FRAM 100a, according to the present embodiment, the bit line 110, FeCap 140, and etch stop layer 150 are the same as those described above in the description of the 3D FeRAM 100 of FIG. 3B. However, as the FeCap 140 is connected to the floating gate FG 120-2 of a storage transistor Sto-Tr, the FeCaps C_{FE} may be additionally arranged in the y direction through the floating gate FG, as indicated by the light solid lines and the dotted lines in FIG. 4A. The FeCaps C_{FE} additionally arranged through connection of the floating gate FG may be included together in a unit pixel Unit-Cell. Furthermore, FIG. 4A shows that word lines WL0 to WL3 are connected to the FeCap C_{FE}, and the word lines WL0 to WL3 may correspond to the plate line electrodes PL of the circuit diagram of the 3D FeRAM 100 of FIG. 1 in terms of circuit connection. Therefore, the word lines WL0 to WL3 may correspond to the second electrodes 145 of FIG. 4B.

In various embodiments, the gate line 120a may include a lower gate line 120-1 and an upper gate electrode 120-2, where the upper gate electrode 120-2 may be separated from the lower gate line 120-1 by a second impurity region ImA2. The lower gate lines 120-1 may extend in the y direction and may be arranged to be spaced apart from each other in the x direction. For example, the lower gate lines 120-1 may be arranged in substantially the same structure as the word lines 120 in the 3D FeRAM 100 of FIG. 3B. The lower gate line 120-1 may constitute a control transistor Con-Tr together with a lower semiconductor pattern 130-1. Therefore, the lower gate line 120-1 may be referred to as a control gate line.

In various embodiments, the upper gate electrode 120-2 may be disposed over the lower gate line 120-1, and may be located at the cross-point location, where the lower gate line 120-1 and the bit line 110 overlap. The upper gate electrode 120-2 has an approximately quadrangular pillar-like shape and may be electrically connected to the first electrode 141 of the FeCap 140 through the top surface of the upper gate electrode 120-2. The upper gate electrode 120-2 may constitute the storage transistor Sto-Tr together with an upper semiconductor pattern 130-2. Also, because power may not be connected to the upper gate electrode 120-2, the upper gate electrode 120-2 may be in a floating state. Therefore, the upper gate electrode 120-2 may be referred to as the floating gate FG.

In various embodiments, the semiconductor pattern 130a may include the lower semiconductor pattern 130-1 and the upper semiconductor pattern 130-2. The lower semiconductor pattern 130-1 may include a lower channel region 132-1 and a lower impurity region 135-1. The upper semiconductor pattern 130-2 may include an upper channel region 132-2 and an upper impurity region 135-2.

In various embodiments, the lower channel region 132-1 may be disposed on both sides of the lower gate line 120-1 in the x direction with a lower gate dielectric layer 122-1 therebetween. The lower impurity region 135-1 may be disposed on both sides of the lower channel region 132-1 in the z direction. For example, the lower impurity region 135-1 may include a first impurity region ImA1 disposed below the lower channel region 132-1 in the z direction and a second impurity region ImA2 disposed above the lower channel region 132-1 in the z direction.

In various embodiments, the upper channel region 132-2 may surround four side surfaces of the upper gate electrode 120-2 with an upper gate dielectric layer 122-2 therebetween. The upper impurity region 135-2 may be disposed on both sides of the upper channel region 132-2 in the z direction. For example, the upper impurity region 135-2 may include the second impurity region ImA2 disposed below the upper channel region 132-2 in the z direction and a third impurity region ImA3 disposed above the upper channel region 132-2 in the z direction. The second impurity region ImA2 may correspond to a shared impurity region commonly used by the lower impurity region 135-1 and the upper impurity region 135-2.

In various embodiments, the source lines 160 may extend parallel to the bit lines 110 in the x direction and may be arranged to be spaced apart in the y direction, where the source lines 160 may be above the bit lines 110 and separated from the bit lines 110 by the first insulation layer 103a. The source line 160 may be electrically connected to the upper semiconductor pattern 130-2. The source line 160 may be electrically connected to the third impurity region ImA3 of the upper semiconductor pattern 130-2. The source line 160 may be located above the upper gate electrode 120-2 and immediately below the etch stop layer 150 in the z direction.

In various embodiments, the 3D FeRAM 100a has a 2TnC structure, and the FeCap 140 may have the shape of a pillar laid down in a side direction, e.g., the x direction. Therefore, the MW per unit area of the 3D FeRAM 100a may be significantly increased. Also, as compared to the VS-DRAM structure, in the 3D FeRAM 100a, the control transistor Con-Tr and the storage transistor Sto-Tr are arranged and there is no cell transistor for each layer, and thus it may be greatly advantageous in terms of process difficulty/distribution.

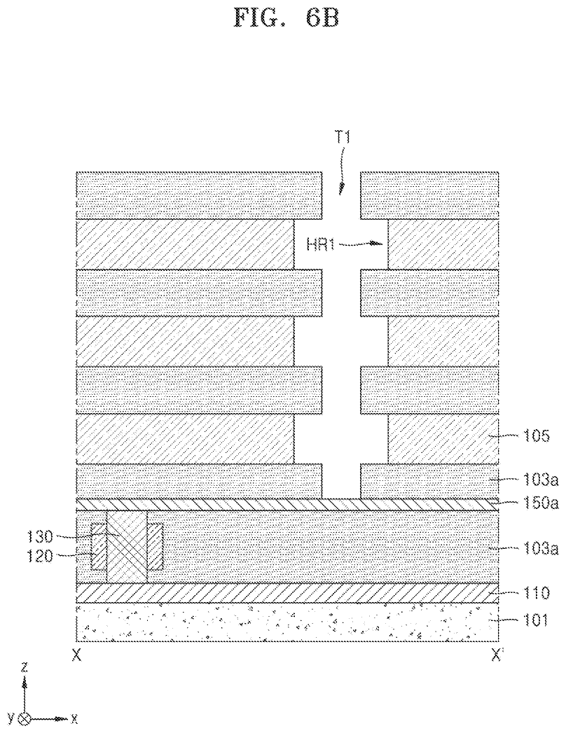

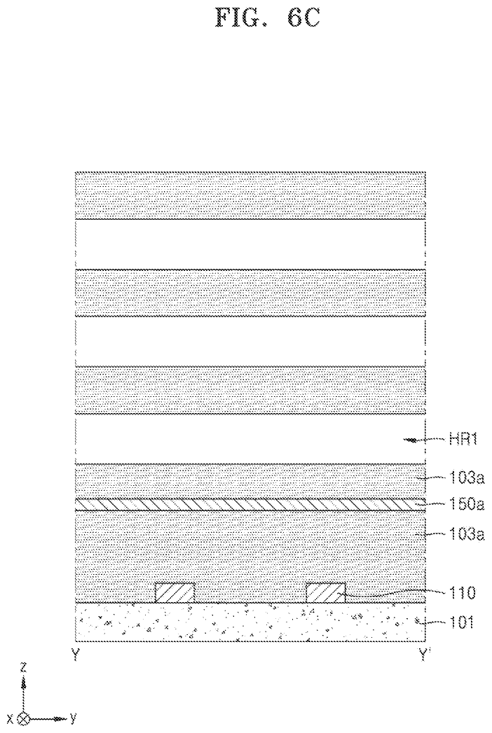

FIGS. 5A to 15C are a plan view and cross-sectional views schematically showing the process of manufacturing the 3D FeRAM of FIG. 2B. FIGS. 6A, 7A, 8A, 9A, 10A, 11A, 12A, 13A, 14A, and 15A correspond to FIG. 3A, FIGS. 5A, 6B, 7B, 8B, 9B, 10B, 11B, 12B, 13B, 14B, and 15B corresponds to FIG. 3B, and FIGS. 5B, 6C, 7D, 8D, 9D, 10D, 11D, 12D, 13D, 14D, and 15D correspond to FIG. 3D. Furthermore, for convenience of understanding, in FIGS. 6A, 7A, 8A, and 9A, a portion Y-Y′ is slightly moved toward a line cut region L-C. Descriptions of 5A to 15C will be given below with reference to FIGS. 3A to 3C, and descriptions already given above with reference to FIGS. 1 to 3C will be briefly given or omitted.

Referring to FIGS. 5A and 5B, according to a method of manufacturing the 3D FeRAM 100, the bit line 110, the word line 120, the semiconductor pattern 130, and an etch stop layer 150a are formed on the substrate 101. As described above, the bit lines 110 may extend in the x direction on the substrate 101 and may be arranged to be spaced apart from each other in the y direction. The word lines 120 may be arranged over the substrate 101 and above the bit lines 110 in the z direction, extend in the y direction, and be spaced apart from each other in the x direction. The semiconductor patterns 130 may be arranged at certain predefined intervals in the x direction and y direction, where the semiconductor patterns 130 may form an array. For example, the semiconductor patterns 130 are arranged where the bit lines 110 are arranged in the x direction and may also be arranged to be spaced apart from each other on corresponding word lines 120 in the y direction with the gate dielectric layer 122 therebetween. The etch stop layer 150a may be disposed on the entire surface of the substrate over the bit line 110, the word line 120, and the semiconductor pattern 130. A first insulation layer 103a may be on the bit lines 110 and substrate 101, and the etch stop layer 150a formed on the first insulation layer 103a, where the first insulation layer 103a can separate the bit lines 110 from the etch stop layer 150a.

In various embodiments, first insulation layer(s) 103a and sacrificial layer(s) 105 are alternately stacked on the etch stop layer 150a. The first insulation layer 103a and the sacrificial layer 105 may include materials that have an etch selectivity with respect to each other, where for example, the first insulation layer 103a may include an oxide layer such as a silicon oxide (SiO₂) layer, and the sacrificial layer 105 may include a nitride layer such as a silicon nitride (SiNx) layer. However, the materials constituting the first insulation layer 103a and the sacrificial layer 105 are not limited to the above-stated materials. The etch stop layer 150a may include a material having an etch selectivity with respect to the first insulation layer 103a and the sacrificial layer 105. However, because the first insulation layer 103a is formed directly on the etch stop layer 150a, according to some embodiments, the etch stop layer 150a may include a material having an etch selectivity with respect to the first insulation layer 103a, e.g., a nitride layer.

Referring to FIGS. 6A to 6C, after the first insulation layer 103a and the sacrificial layer 105 are formed, a first trench T1 corresponding to the line cut region L-C is formed. The first trench T1 extends in the y direction, and may penetrate through the first insulation layer 103a and the sacrificial layer 105 and expose the etch stop layer 150a. Therefore, the line cut region L-C may have a shape extending in the y direction with a certain width in the x direction on the x-y plane.

In various embodiments, the first insulation layer 103a and the sacrificial layer 105 may be exposed to the inner wall of the first trench T1. After the first trench T1 is formed, an exposed portion of the sacrificial layer 105 is removed through a partial pull-back process. As a portion of the sacrificial layer 105 is removed through the partial pull-back process, a first horizontal recess HR1 may be formed at a location where the sacrificial layer 105 is located within the first trench T1.

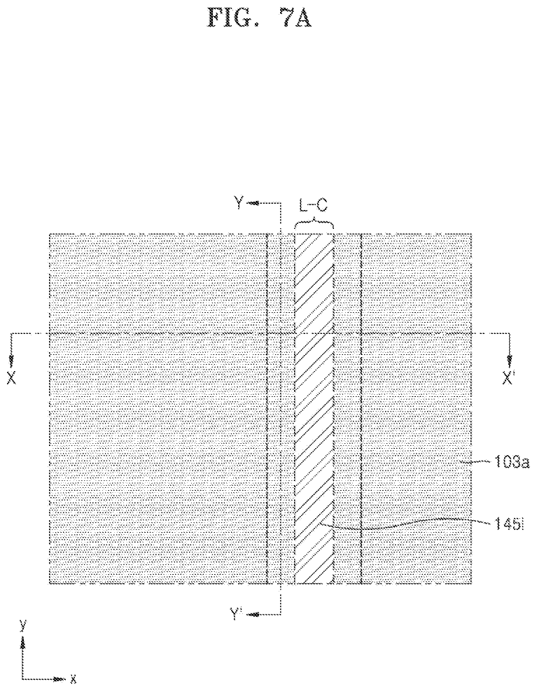

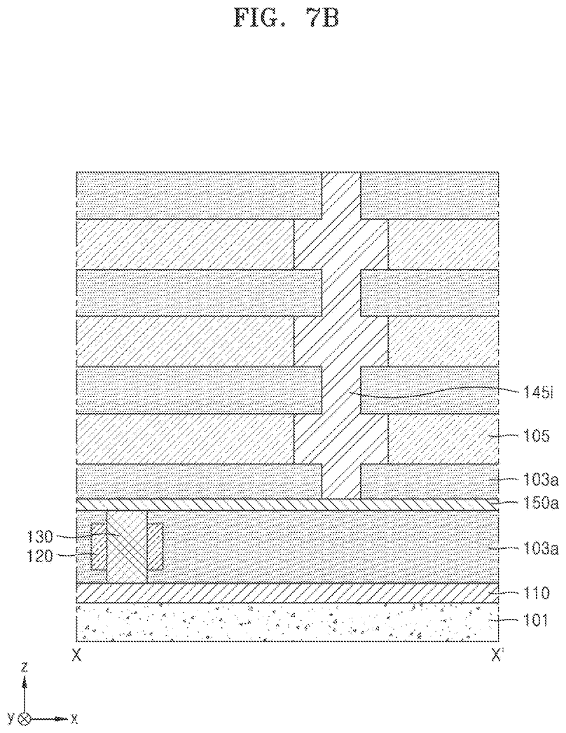

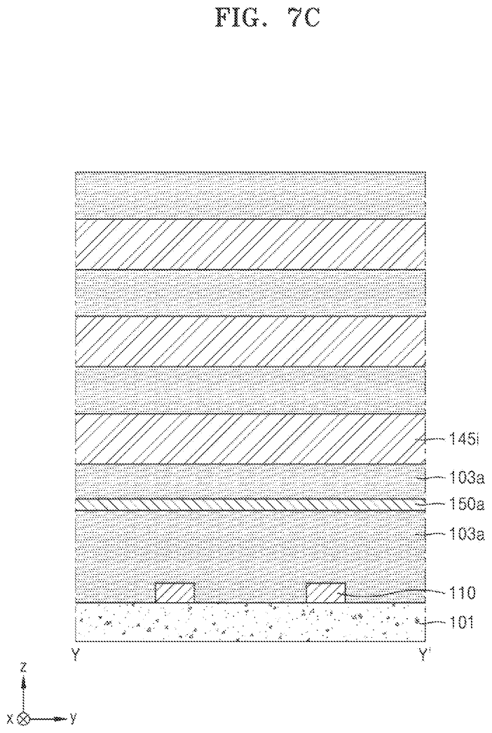

Thereafter, referring to FIGS. 7A to 7C, the first trench T1 and the first horizontal recess HR1 are filled with a second electrode material layer 1451. For example, the second electrode material layer 1451 may include, but not be limited to, a doped semiconductor material, a metal, a conductive metal nitride, and a conductive metal oxide. In FIG. 7A, the dotted line outside the line cut region L-C in the x direction indicates a region in which a space formed by removing the portion of sacrificial layer 105 therebelow is filled with the second electrode material layer 1451.

Referring to FIGS. 8A to 8C, the first trench T1 corresponding to the line cut region L-C is formed again. The first trench T1 extends in the y direction, may penetrate through the second electrode material layer 1451 and the sacrificial layer 105, and expose the etch stop layer 150a. As the first trench T1 is again formed, second electrode material layers 1451 on different layers in the z direction may be separated from each other, where portions of first insulation layer 103a can be located vertically between the separate second electrode material layers 1451. The interlayer separation process of an electrode layer is called a node separation process. The initial second electrode(s) 145i may be formed through the node separation process. In FIG. 8A, the dotted line outside the line cut region L-C in the x direction indicates a region in which a space formed by removing the portion of sacrificial layer 105 therebelow is filled with the initial second electrode 145i.

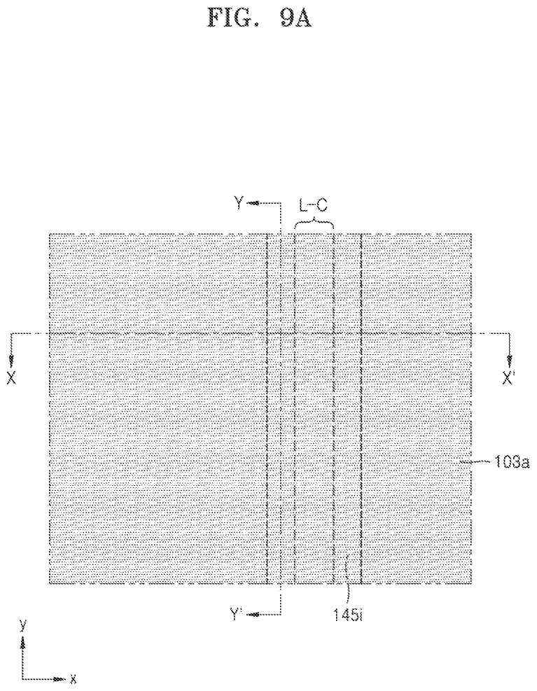

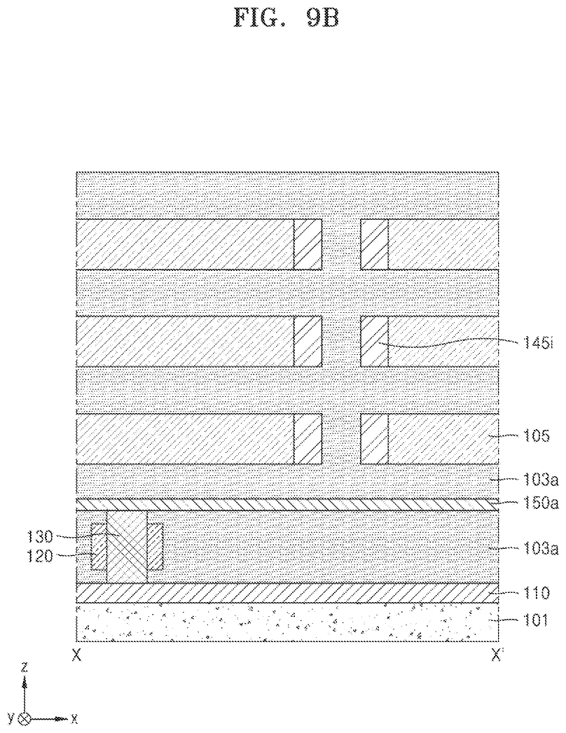

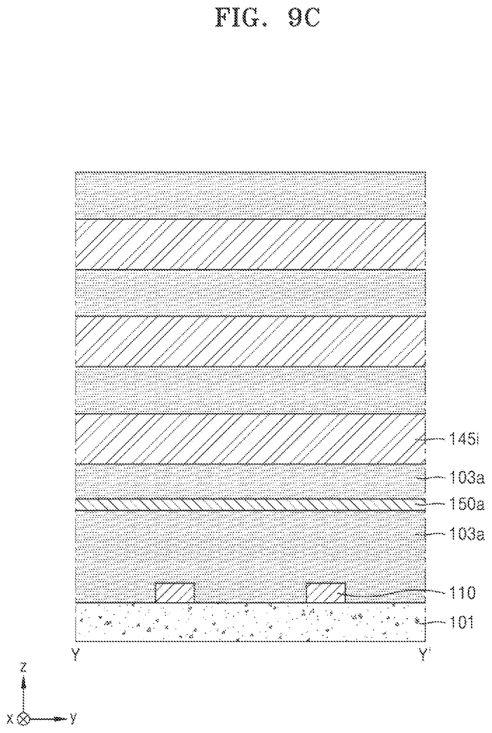

Referring to FIGS. 9A to 9C, the first trench T1 is then filled with substantially the same material as first insulation layer 103a. In FIG. 9A, the dotted line outside the line cut region L-C in the x direction indicates a region in which the initial second electrode 145i is formed in a space formed by removing the portion of sacrificial layer 105 therebelow.

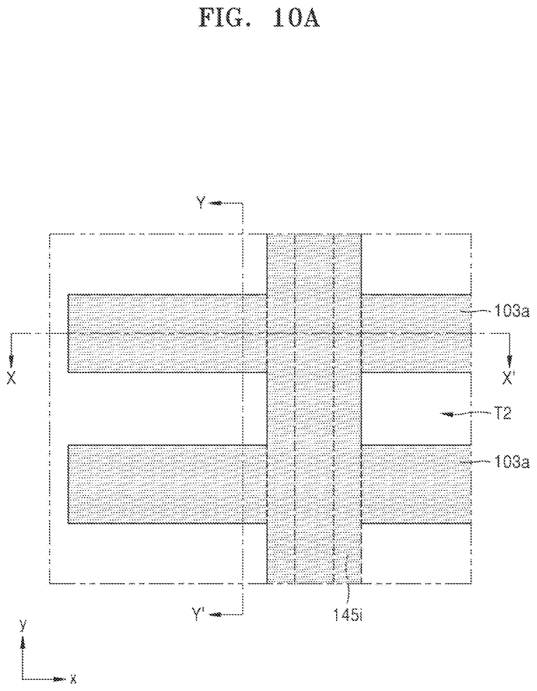

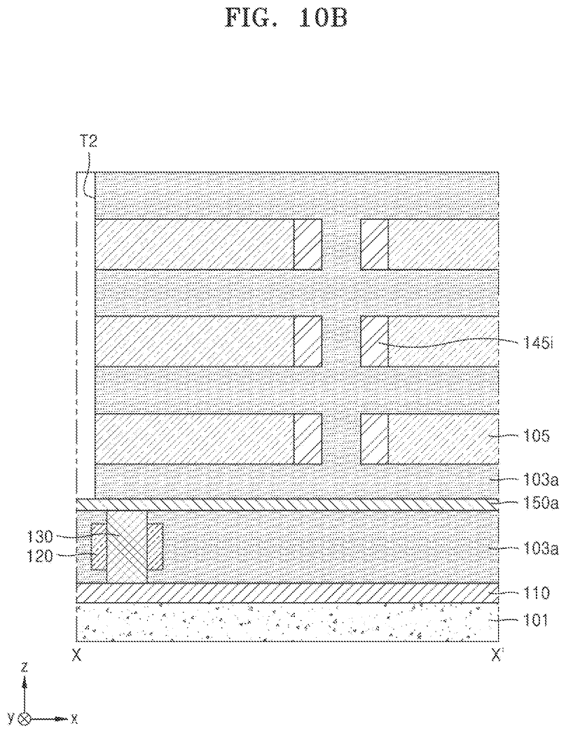

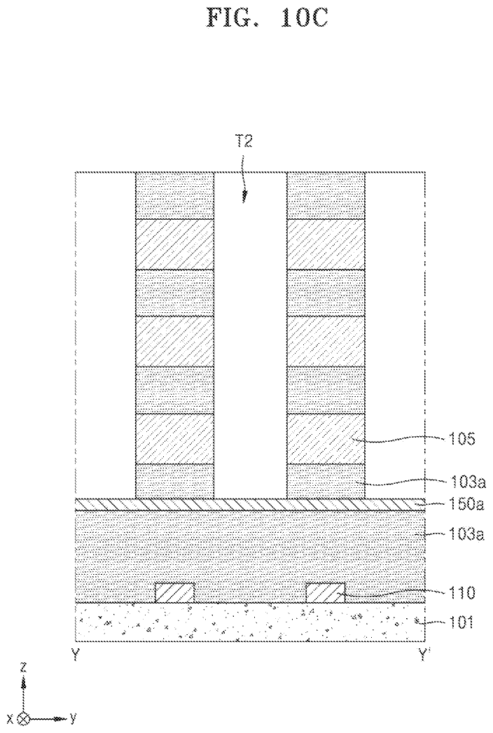

Referring to FIGS. 10A to 10C, after the initial second electrode 145i is formed, a second trench T2 is formed to separate nodes of the FeCap 140. The second trench T2 may be formed as follows. First, a mask having a shape corresponding to the solid lines shown in FIG. 10A is formed on the uppermost first insulation layer 103a. Thereafter, the first insulation layer 103a and the sacrificial layer 105 therebelow are removed through an etching process using the mask, thereby forming the second trench T2. The etch stop layer 150a may be exposed through the bottom surface of the second trench T2, where removal of the first insulation layer 103a and the sacrificial layer 105 stops at the etch stop layer 150a.

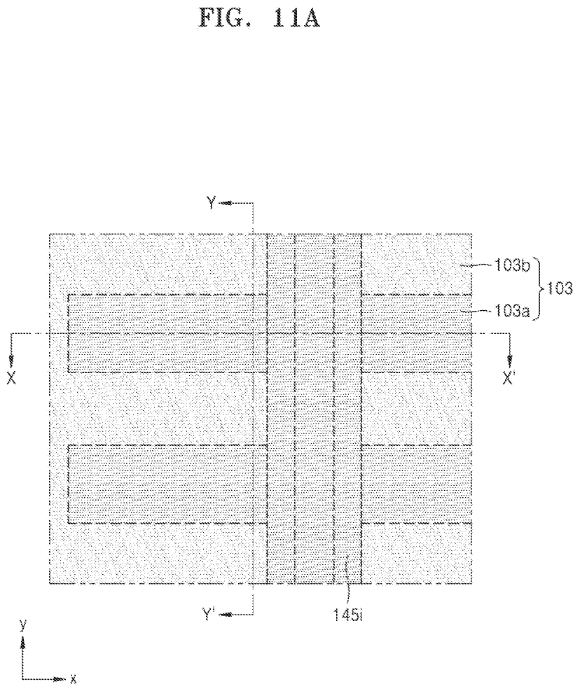

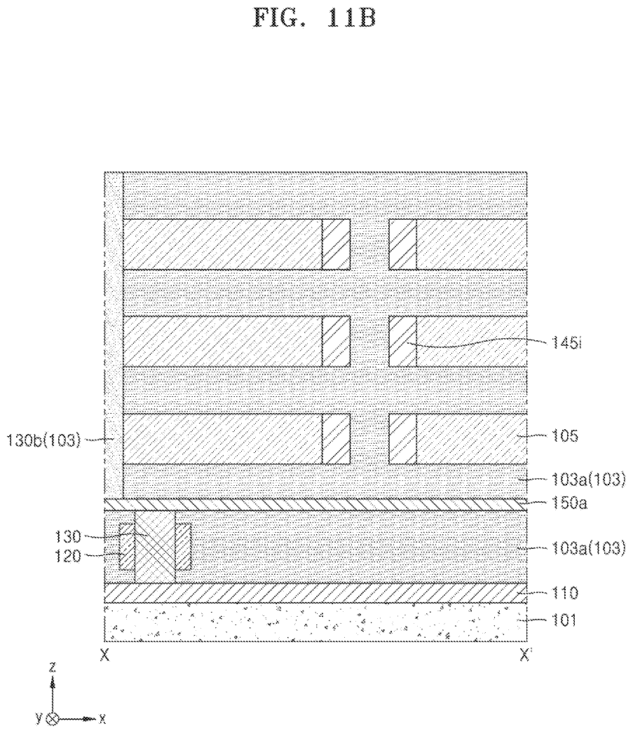

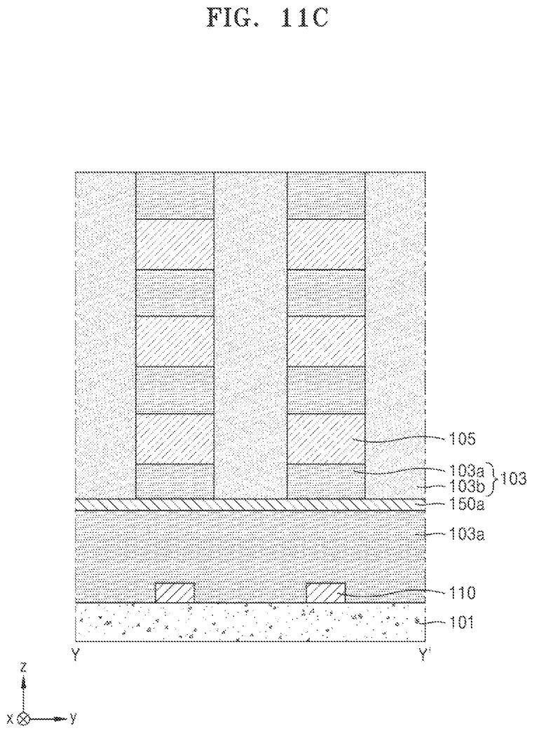

Referring to FIGS. 11A to 11C, after the second trench T2 is formed, the second trench T2 is filled with the second insulation layer 103b. The second insulation layer 103b may include substantially the same material as the first insulation layer 103a, e.g., an oxide layer. As described above, the difference between the first insulation layer 103a and the second insulation layer 103b may be merely time of formation. For example, the insulation layer 103 formed before the second trench T2 is formed may be the first insulation layer 103a, and the insulation layer 103 formed after the second trench T2 is formed may be the second insulation layer 103b.

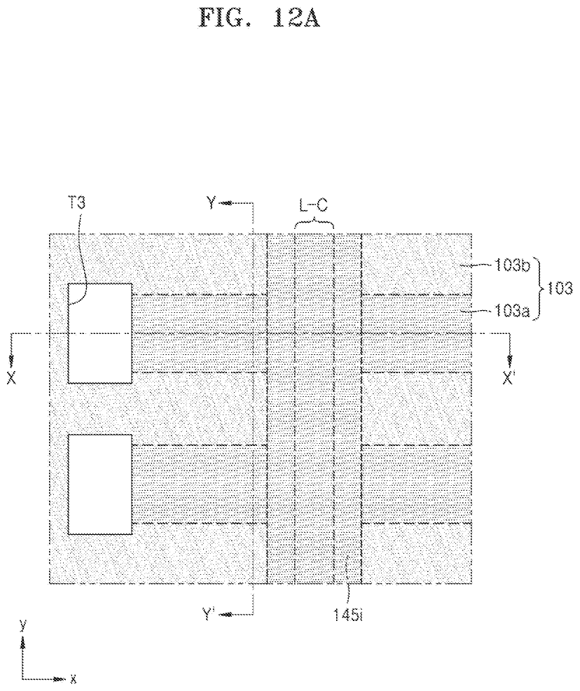

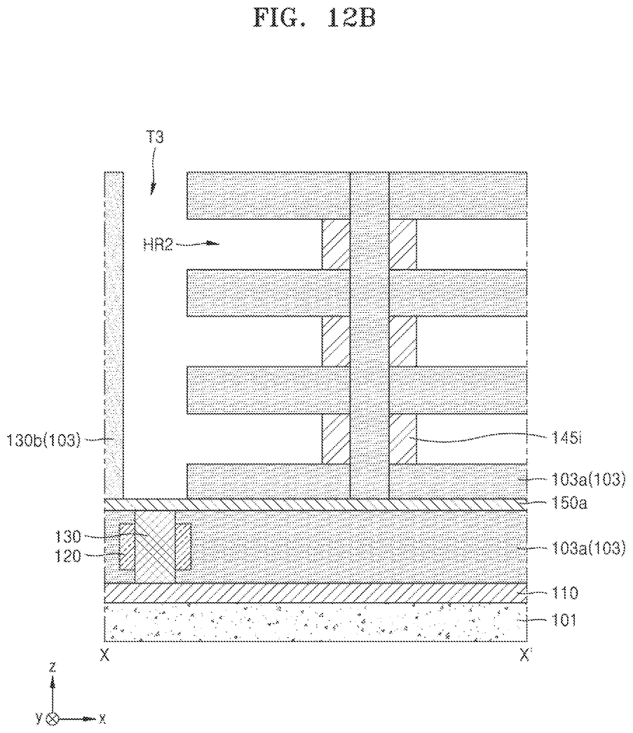

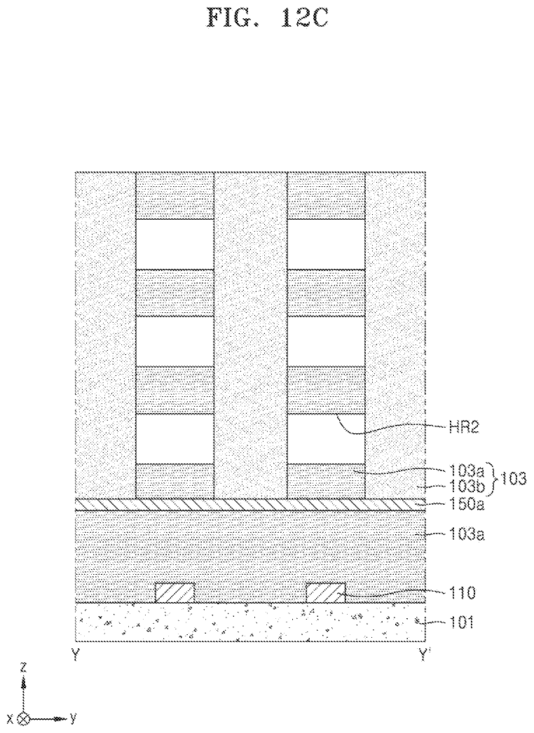

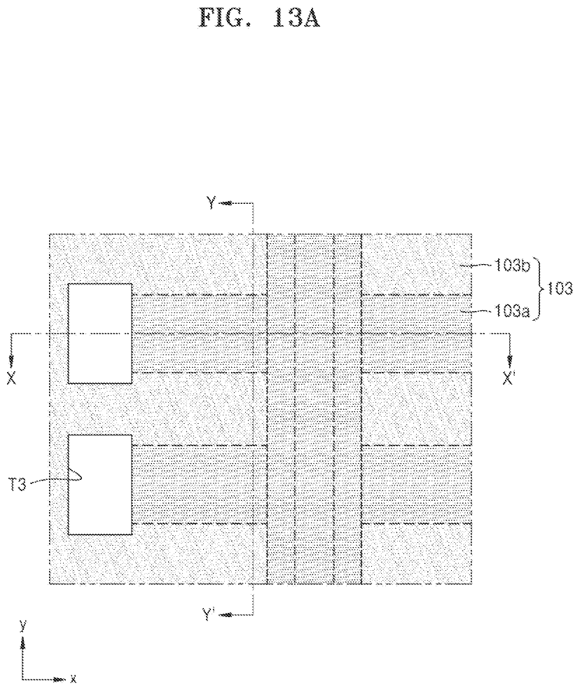

Referring to FIGS. 12A to 12C, after the second insulation layer 103b is formed, a third trench T3 is formed to form the FeCap 140. The third trench T3 may be formed at a location where the semiconductor pattern 130 or the selection transistor S-Tr is disposed, on the x-y plane. As shown in FIG. 12A, the horizontal cross-section of the third trench T3 may have a quadrangular shape. The insulation layer 103 and the sacrificial layer 105 may be exposed along the sidewalls of the third trench T3, and the etch stop layer 150a may be exposed at the bottom of the third trench T3.

After forming the third trench T3, an exposed portion of the sacrificial layer 105 is removed through a pull-back process. As the sacrificial layer 105 is completely removed through the pull-back process, a second horizontal recess HR2 may be formed on one side surface of the third trench T3 in the x direction, where the extent (e.g., depth) of the pull-back process can determine the length of the horizontal extensions 141hc.

Thereafter, referring to FIGS. 13A to 13C, a second electrode material layer filling the third trench T3 and the second horizontal recess HR2 is formed to a certain thickness. The second electrode material layer may be substantially the same as the second electrode material layer 1451 shown in FIGS. 7A to 7C. Thereafter, the third trench T3 is formed again. Through the formation of the third trench T3, the second electrode material layer at different layers are separated from each other. In other words, node separation of the second electrode material layer is performed through the formation of the third trench T3. The second electrodes 145 may be completed through the node separation.

As indicated by the dotted lines in FIG. 13B, a closed portion of the cover portion 145c of the second electrode 145 is a merged result of the initial second electrode 145i and the second electrode material layer filling the second horizontal recess HR2. Therefore, the closed portion of the cover portion 145c may be thicker than four side portions of the cover portion 145c.

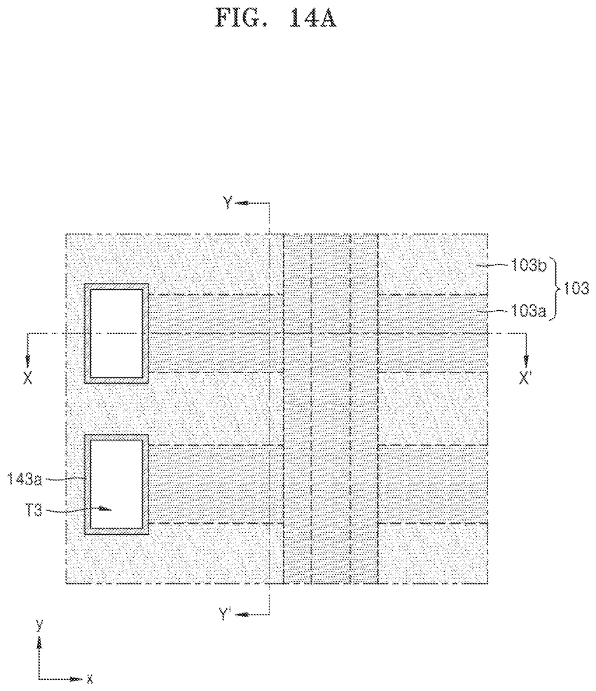

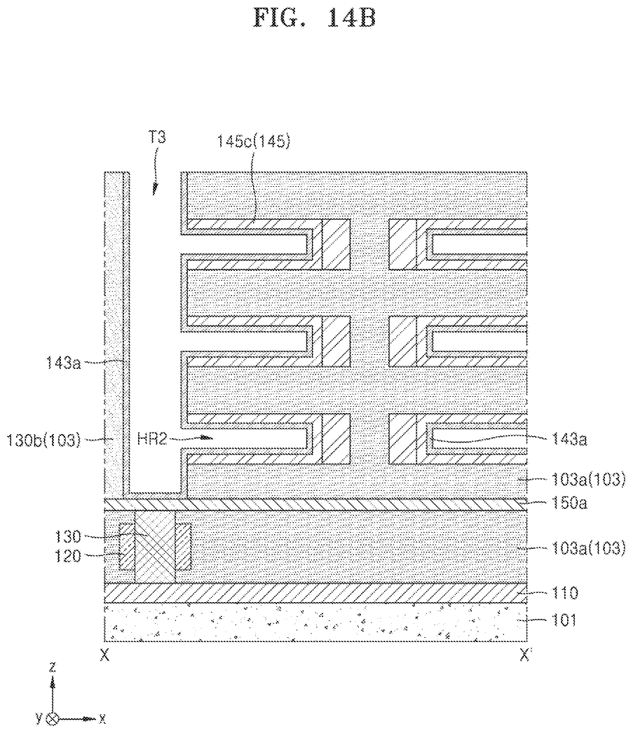

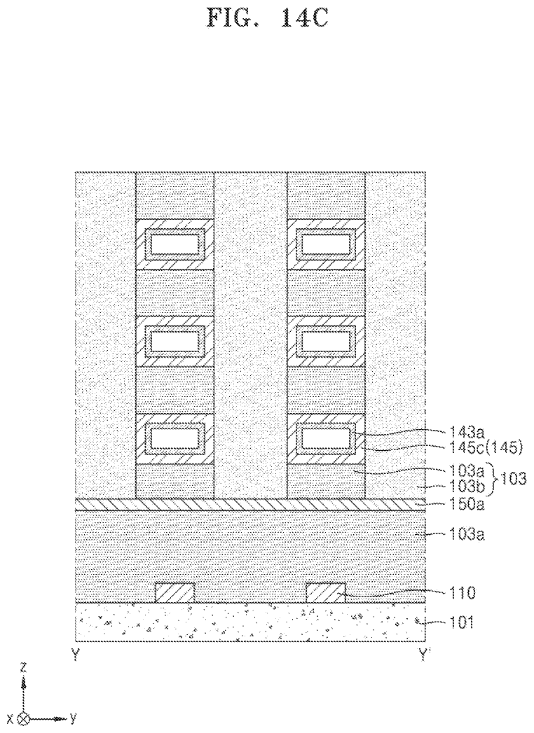

Referring to FIGS. 14A to 14C, after the second electrode 145 is formed, a ferroelectric layer 143a filling the third trench T3 and the second horizontal recess HR2 is formed to a certain thickness. The ferroelectric layer 143a may be formed on side surfaces and the bottom surface of the third trench T3 and on the second electrode 145 within the second horizontal recess HR2. The material constituting the ferroelectric layer 143a is the same as those described in the description of the 3D FeRAM 100 of FIGS. 3A to 3C.

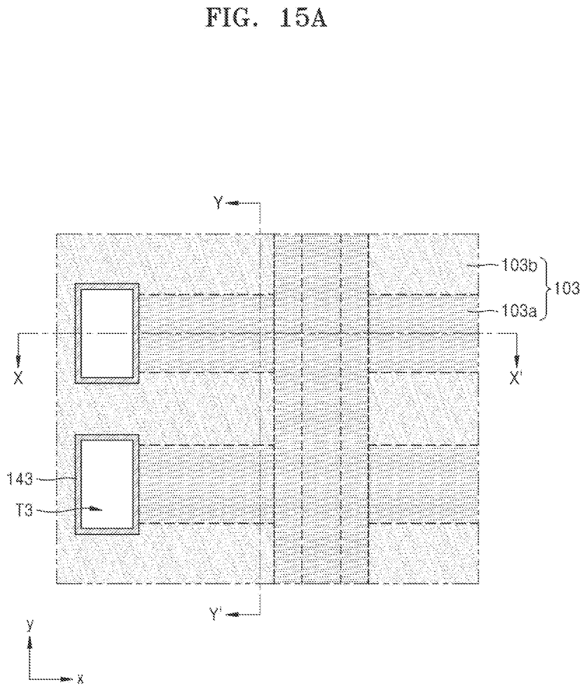

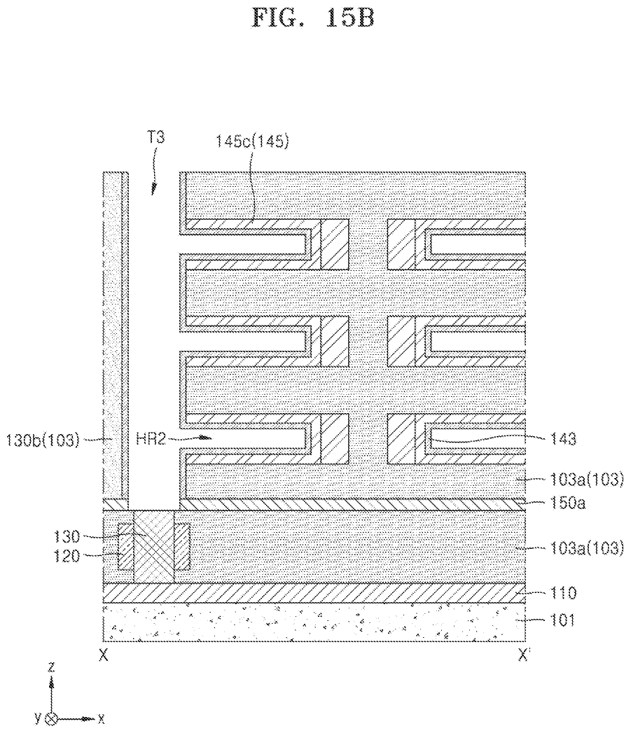

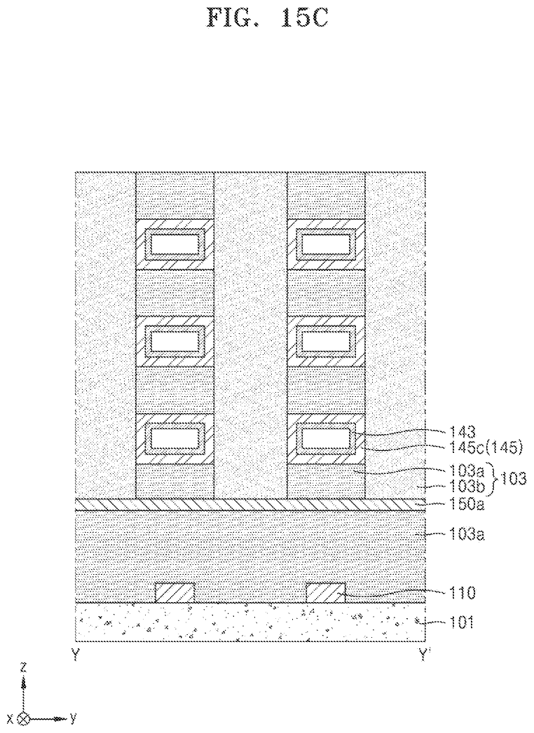

Thereafter, referring to FIGS. 15A to 15C, the ferroelectric layer 143a on the bottom surface of the third trench T3 is removed. The ferroelectric layer 143 may be completed by removing the ferroelectric layer 143a on the bottom surface of the third trench T3. Also, the etch stop layer 150a may be exposed through the bottom of the third trench T3. Subsequently, the portion of the etch stop layer 150a exposed at the bottom surface of the third trench T3 is removed to expose the semiconductor pattern 130.

Thereafter, the first electrode 141 filling the third trench T3 and the second horizontal recess HR2 is formed. The 3D FeRAM 100 of FIG. 3B may be completed by forming the first electrode 141. An impurity doping process may be performed on the semiconductor pattern 130 through the third trench T3 before the first electrode 141 is formed in the third trench T3.

While the disclosure has been particularly shown and described with reference to embodiments thereof, it will be understood that various changes in form and details may be made therein without departing from the spirit and scope of the following claims.

What is claimed is:

1. A three-dimensional (3D) ferroelectric random access memory (FeRAM) comprising:
bit lines extending in a first horizontal direction on a substrate and spaced apart from each other in a second horizontal direction perpendicular to the first horizontal direction;
word lines disposed over the bit line, extending in the second horizontal direction, and spaced apart from each other in the first horizontal direction;
semiconductor patterns arranged at intervals on corresponding portions of the word lines with a gate dielectric layer therebetween; and
ferroelectric capacitor (FeCap) structures over the semiconductor patterns in the vertical direction,
wherein the FeCap structures comprise:
a first electrode comprising a body portion extending in the vertical direction from a semiconductor pattern and at least two horizontal extensions extending from side surfaces of the body portion in the first horizontal direction and located at different levels;
a ferroelectric layer covering outer walls of the body portion and the horizontal extensions; and
second electrodes covering the ferroelectric layer on the horizontal extensions.

2. The 3D FeRAM of claim 1, wherein, between the horizontal extensions, the body portion has a quadrangular shape, and the ferroelectric layer covering the outer walls of the body portion has a quadrangular ring-like shape.

3. The 3D FeRAM of claim 1, wherein a horizontal extension has a shape of a quadrangular pillar oriented in the first horizontal direction.

4. The 3D FeRAM of claim 3, wherein the ferroelectric layer of the horizontal extension has a shape of a quadrangular tube oriented in the first horizontal direction with a distal end closed,
a cross-section of the ferroelectric layer of the horizontal extension perpendicular to the first horizontal direction has a quadrangular ring-like shape, and
a cross-section of the ferroelectric layer of the horizontal extension perpendicular to the second horizontal direction has a ‘⊏’ shape.

5. The 3D FeRAM of claim 3, wherein the second electrode has a shape of a quadrangular tube oriented in the first horizontal direction with a distal end closed,
a cross-section of the second electrode perpendicular to the first horizontal direction has a quadrangular ring-like shape, and
a cross-section of the second electrode perpendicular to the second horizontal direction has a ‘⊏’ shape.

6. The 3D FeRAM of claim 5, wherein the closed distal end of the quadrangular tube-like portion of the second electrode is thicker than four sides of the quadrangular tube-like portion of the second electrode, and the second electrode comprises an extension extending from the closed distal end of the quadrangular tube-like portion in the second horizontal direction, and
second electrodes located at a same level in the vertical direction are connected to each other through the extension.

7. The 3D FeRAM of claim 1, wherein an etch stop layer is on a surface of the substrate over the bit lines, word lines, and semiconductor patterns, and
the body portion penetrates the etch stop layer and is electrically connected to the semiconductor patterns.

8. The 3D FeRAM of claim 1, wherein the word lines are arranged on both sides of the semiconductor pattern in the first direction, and
the semiconductor pattern comprises a channel region in a central portion of the semiconductor pattern in the vertical direction and impurity regions between the channel region and the bit lines, and between the channel region and the body portion in the vertical direction.

9. The 3D FeRAM of claim 1, wherein the semiconductor patterns are arranged on both side surfaces of a word line in the first direction, and
the 3D FeRAM further comprises a gate electrode on the word line and electrically connected to the body portion,
an upper semiconductor pattern surrounds four side surfaces of the gate electrode with an upper gate dielectric layer therebetween, and
a source line connected to the upper semiconductor pattern and extending in the first horizontal direction.

10. The 3D FeRAM of claim 9, wherein the semiconductor pattern comprises the channel region at the central portion of the semiconductor pattern in the vertical direction, a first impurity region below the channel region, and a second impurity region above the channel region, and
the upper semiconductor pattern comprises an upper channel region in a central portion of the upper semiconductor pattern, the second impurity region below the upper channel region, and a third impurity region above the upper channel region.

11. The 3D FeRAM of claim 9, wherein an etch stop layer is on asurface of the substrate over the gate electrode and the source line, and
the body portion penetrates the etch stop layer and is electrically connected to the gate electrode.

12. A three-dimensional (3D) ferroelectric random access memory (FeRAM) comprising:
a substrate;
bit lines extending in a first horizontal direction on the substrate and spaced apart from each other in a second horizontal direction perpendicular to the first horizontal direction;
a selection transistor (Tr) comprising word lines arranged over the bit lines in a vertical direction, extending in the second horizontal direction, and spaced apart from each other in the first horizontal direction, and semiconductor patterns arranged at intervals on corresponding portions of the word lines with a gate dielectric layer therebetween in the second horizontal direction; and
a FeCap structure having a plurality of capacitors on the selection Tr
wherein the FeCap structure comprises:
a first electrode comprising a body portion extending in the vertical direction from a semiconductor pattern and n horizontal extensions extending from a side surface of the body portion in the first horizontal direction;
a ferroelectric layer covering outer walls of the body portion and the horizontal extensions; and
a plurality of second electrodes covering the ferroelectric layer of the horizontal extensions,
wherein the 3D FeRAM has a structure in which the plurality of FeCaps are electrically connected to one selection Tr.

13. The 3D FeRAM of claim 12, wherein the horizontal extensions have a shape of a quadrangular pillar oriented in the first horizontal direction,
the ferroelectric layer of the horizontal extension has a shape of a quadrangular tube with a distal end closed in the first horizontal direction,
a cross-section of the ferroelectric layer of the horizontal extension perpendicular to the first horizontal direction has a quadrangular ring-like shape, and
a cross-section of the ferroelectric layer of the horizontal extension perpendicular to the second horizontal direction has a ‘⊏’ shape.

14. The 3D FeRAM of claim 12, wherein the second electrode has a shape of a quadrangular tube with a distal end closed in the first horizontal direction,
a cross-section of the second electrode perpendicular to the first horizontal direction has a quadrangular ring-like shape,
a cross-section of the second electrode perpendicular to the second horizontal direction has a ‘⊏’ shape,
the second electrode comprises an extension extending from a closed side of a quadrangular tube-like portion in the second horizontal direction, and
second electrodes located at a same level in the vertical direction are connected to each other through the extension.

15. The 3D FeRAM of claim 12, wherein an etch stop layer is on an entire surface of the substrate over the bit lines, word lines, and semiconductor patterns,
the word lines are arranged on both sides of the semiconductor pattern in the first direction,
the semiconductor pattern comprises a channel region in a central portion of the semiconductor pattern in the vertical direction and impurity regions between the channel region and the bit lines and between the channel region and the body portion in the vertical direction, and
the body portion penetrates the etch stop layer and is connected to the impurity regions.

16. A three-dimensional (3D) ferroelectric random access memory (FeRAM) comprising:
a substrate;
bit lines extending in a first horizontal direction on the substrate and spaced apart from each other in a second horizontal direction perpendicular to the first horizontal direction;
at least one transistor (TR) on the bit line; and
a FeCap structure on the at least one TR,
wherein the FeCap structure comprises:
a first electrode comprising a body portion extending in a vertical direction from the at least one Tr and a plurality of horizontal extensions extending in the first horizontal direction from a side surface of the body portion and located at different levels;
a ferroelectric layer covering outer walls of the body portion and the horizontal extensions; and
a plurality of second electrodes covering the ferroelectric layer on the horizontal extensions.

17. The 3D FeRAM of claim 16, wherein the at least one TR comprises one selection Tr, and
the one selection Tr comprises:
word lines disposed over the bit line in a vertical direction, extending in the second horizontal direction, and spaced apart from each other in the first horizontal direction;
channel regions arranged at intervals on corresponding portions of the word lines with a gate dielectric layer therebetween in the second horizontal direction; and
impurity regions arranged on both sides of the channel regions in the vertical direction.

18. The 3D FeRAM of claim 17, wherein a horizontal extension has a shape of a quadrangular pillar laid down in the first horizontal direction, and,
when the first electrode, the ferroelectric layer of the horizontal extensions, and the second electrode constitute one FeCap, the 3D FeRAM has a structure in which a plurality of FeCaps are connected to the one selection Tr.

19. The 3D FeRAM of claim 16, wherein the at least one Tr comprises a first Tr, which is a lower Tr, and a second Tr is an upper Tr, and
the first Tr comprises:
gate lines over the bit line in a vertical direction, extending in the second horizontal direction, and spaced apart from each other in the first horizontal direction;
channel regions arranged at a certain interval on corresponding portions of the gate lines in the second horizontal direction and arranged on both side surfaces of the gate lines in the first horizontal direction with a gate dielectric layer therebetween; and
a first impurity region below the channel regions in the vertical direction and a second impurity region disposed above the channel regions.

20. The 3D FeRAM of claim 19, wherein the second Tr comprises:
a gate electrode over a gate line and connected to the body portion,
an upper channel region surrounding four side surfaces of the gate electrode with an upper gate dielectric layer therebetween; and
the second impurity region below the upper channel region and a third impurity region above the upper channel region in the vertical direction, and
the 3D FeRAM further comprises a source line extending in the first horizontal direction and connected to the third impurity region.
